(19) United States
(12) Patent Application Publication
(10) Pub. No.: US 2023/0335685 A1
(43) Pub. Date: Oct. 19, 2023

(54) PHOSPHOR BOARD, LIGHT-EMITTING SUBSTRATE, AND LIGHTING APPARATUS

(71) Applicant: DENKA COMPANY LIMITED, Tokyo (JP)

(72) Inventor: Masahiro KONISHI, Tokyo (JP)

(73) Assignee: DENKA COMPANY LIMITED, Tokyo (JP)

(21) Appl. No.: 18/022,663

(22) PCT Filed: Aug. 20, 2021
(86) PCT No.: PCT/JP2021/030626

§ 371 Date: Feb. 22, 2023

(30) Foreign Application Priority Data
Aug. 28, 2020 (JP) 2020-144279

(51) Int. Cl. H01L 33/50; H01L 25/075

(52) U.S. Cl. CPC H01L 33/505; H01L 25/0753; H01L 33/502

(57) ABSTRACT

A phosphor board over which at least one light-emitting element is mounted, the phosphor board including an insulating substrate, a circuit pattern layer which is disposed over one surface of the insulating substrate and which is to be bonded to the at least one light-emitting element, a phosphor layer which is disposed over one surface side of the insulating substrate and which includes phosphor for which a light emission peak wavelength is in a visible light region when the emitted light of the at least one light-emitting element is used as excitation light, and a support layer which is disposed between the insulating substrate and the phosphor layer, which is a layer that does not include the phosphor, and which supports the phosphor layer.

### TECHNICAL FIELD

The present invention relates to a phosphor board, a light-emitting substrate, and a lighting apparatus.

### BACKGROUND ART

Patent Document 1 discloses a light-emitting diode (LED) lighting fixture provided with a substrate on which a light-emitting element (LED element) is mounted. This LED lighting fixture is provided with a reflective material on the surface of the substrate to improve the light-emitting efficiency.

### RELATED DOCUMENT

### Patent Document

[Patent Document 1] Chinese Patent Publication No. 106163113

### SUMMARY OF THE INVENTION

### Technical Problem

However, in the case of the configuration disclosed in Patent Document 1, it was not possible to adjust the light emitted by the LED lighting fixture using a reflective material to be light emitted with a color different from the light emitted by the light-emitting element and the glare counter-measures were insufficient.

The present invention has an object of providing a phosphor board capable of reducing the glare of light emitted by a light-emitting element in a case where the light-emitting element is mounted thereon.

### Solution to Problem

A phosphor board of a first aspect of the present invention is a phosphor board over which at least one light-emitting element is mounted, the phosphor board including an insulating substrate, a circuit pattern layer which is disposed over one surface of the insulating substrate and which is to be bonded to the at least one light-emitting element, a phosphor layer which is disposed over the one surface side of the insulating substrate and which includes phosphor for which a light emission peak wavelength is in a visible light region when emitted light of the at least one light-emitting element is used as excitation light, and a support layer which is disposed between the insulating substrate and the phosphor layer, which is a layer that does not include the phosphor, and which supports the phosphor layer.

The phosphor board of a second aspect of the present invention is the phosphor board described above in which the support layer has a monolayer structure including a white pigment.

The phosphor board of a third aspect of the present invention is the phosphor board described above in which the support layer is also disposed between a portion of the circuit pattern layer other than a portion to be bonded to the at least one light-emitting element, and the phosphor layer.

The phosphor board of a fourth aspect of the present invention is the phosphor board described above in which the support layer has a multilayer structure in which an adjacent layer that is adjacent to the phosphor layer includes a white pigment.

The phosphor board of a fifth aspect of the present invention is the phosphor board described above in which the support layer is formed of the adjacent layer and a base layer which is disposed between the insulating substrate and the adjacent layer and which does not include a white pigment, and a thickness of the adjacent layer is thinner than a thickness of the base layer.

The phosphor board of a sixth aspect of the present invention is the phosphor board described above in which the adjacent layer is also disposed between a portion of the circuit pattern layer other than a portion to be bonded to the at least one light-emitting element, and the phosphor layer.

The phosphor board of a seventh aspect of the present invention is the phosphor board described above in which the phosphor is formed of a plurality of phosphor particles, the white pigment is formed of a plurality of white particles, and D1₅₀, which is a volume-based median diameter (D₅₀) of the plurality of phosphor particles measured by a laser diffraction scattering method, and D2₅₀, which is a volume-based median diameter (D₅₀) of the plurality of white particles measured by the laser diffraction scattering method, have a relationship as in (Equation 1) below.

$$0.8 \leq {\text{D2}}_{50} / {\text{D1}}_{50} \leq 1.2 \qquad \text{(Equation 1)}$$

The phosphor board of an eighth aspect of the present invention is the phosphor board described above in which a thickness of the phosphor layer is thinner than a thickness of the support layer.

The phosphor board of a ninth aspect of the present invention is the phosphor board described above in which an outer surface of the phosphor layer is positioned outside of an outer surface of the circuit pattern layer, in a thickness direction of the insulating substrate.

The phosphor board of a tenth aspect of the present invention is the phosphor board described above in which the at least one light-emitting element is a plurality of light-emitting elements.

A light-emitting substrate of a first aspect of the present invention includes the phosphor board described above, and the at least one light-emitting element.

A lighting apparatus of a first aspect of the present invention includes the light-emitting substrate described above, and a power supply for supplying power to emit light from the at least one light-emitting element.

### BRIEF DESCRIPTION OF THE DRAWINGS

FIG. 1A is a plan view of a light-emitting substrate of a first embodiment.

FIG. 1B is a bottom view of the light-emitting substrate of the first embodiment.

FIG. 1C is a partial cross-sectional view of the light-emitting substrate cut away on a 1C-1C cut line in FIG. 1A.

FIG. 2A is a plan view of a phosphor board of the first embodiment (the phosphor layer and the support layer are not shown).

FIG. 2B is a plan view of the phosphor board of the first embodiment.

FIG. 3A is an explanatory diagram of a first step in a method for manufacturing a light-emitting substrate of the first embodiment.

FIG. 3B is an explanatory diagram of a second step in the method for manufacturing a light-emitting substrate of the first embodiment.

FIG. 3C is an explanatory diagram of a third step in the method for manufacturing a light-emitting substrate of the first embodiment.

FIG. 3D is an explanatory diagram of a fourth step in the method for manufacturing a light-emitting substrate of the first embodiment.

FIG. 3E is an explanatory diagram of a fifth step in the method for manufacturing a light-emitting substrate of the first embodiment.

FIG. 4 is a diagram for illustrating a light-emitting operation of the light-emitting substrate of the first embodiment.

FIG. 5 is a diagram for illustrating a light-emitting operation of a light-emitting substrate of a comparative form.

FIG. 6 is a partial cross-sectional view of a light-emitting substrate of a second embodiment.

FIG. 7A is an explanatory diagram of a second step in a method for manufacturing the light-emitting substrate of the second embodiment.

FIG. 7B is an explanatory diagram of a third step in the method for manufacturing the light-emitting substrate of the second embodiment.

FIG. 7C is an explanatory diagram of a fourth step in the method for manufacturing the light-emitting substrate of the second embodiment.

FIG. 7D is an explanatory diagram of a fifth step in the method for manufacturing the light-emitting substrate of the second embodiment.

FIG. 8 is a partial cross-sectional view of a light-emitting substrate of a third embodiment.

FIG. 9A is an explanatory diagram of a first half of a second step in a method for manufacturing the light-emitting substrate of the third embodiment.

FIG. 9B is an explanatory diagram of a second half of the second step in the method for manufacturing the light-emitting substrate of the third embodiment.

FIG. 9C is an explanatory diagram of a third step in the method for manufacturing the light-emitting substrate of the third embodiment.

FIG. 9D is an explanatory diagram of a fourth step in the method for manufacturing the light-emitting substrate of the third embodiment.

FIG. 9E is an explanatory diagram of a fifth step in the method for manufacturing the light-emitting substrate of the third embodiment.

FIG. 10 is a partial cross-sectional view of a light-emitting substrate of a fourth embodiment.

FIG. 11A is an explanatory diagram of a second half of a first step in a method for manufacturing the light-emitting substrate of the fourth embodiment.

FIG. 11B is an explanatory diagram of a second step in the method for manufacturing the light-emitting substrate of the fourth embodiment.

FIG. 11C is an explanatory diagram of a third step in the method for manufacturing the light-emitting substrate of the fourth embodiment.

FIG. 11D is an explanatory diagram of a fourth step in the method for manufacturing the light-emitting substrate of the fourth embodiment.

FIG. 11E is an explanatory diagram of a fifth step in the method for manufacturing the light-emitting substrate of the fourth embodiment.

FIG. 12 is a partial cross-sectional view of a light-emitting substrate of a fifth embodiment.

FIG. 13A is an explanatory diagram of a first half of a second step in a method for manufacturing the light-emitting substrate of the fifth embodiment.

FIG. 13B is an explanatory diagram of a second half of a second step in the method for manufacturing the light-emitting substrate of the fifth embodiment.

FIG. 13C is an explanatory diagram of a third step in the method for manufacturing the light-emitting substrate of the fifth embodiment.

FIG. 13D is an explanatory diagram of a fourth step in the method for manufacturing the light-emitting substrate of the fifth embodiment.

FIG. 13E is an explanatory diagram of a fifth step in the method for manufacturing the light-emitting substrate of the fifth embodiment.

### DESCRIPTION OF EMBODIMENTS

### Overview

A description will be given of the first to fifth embodiments, which are examples of the present invention, in the described order. Next, a description will be given of modifications of these embodiments. In all drawings referred to in the following description, the same constituent components will be marked with the same reference numerals and not be repeated.

### First Embodiment

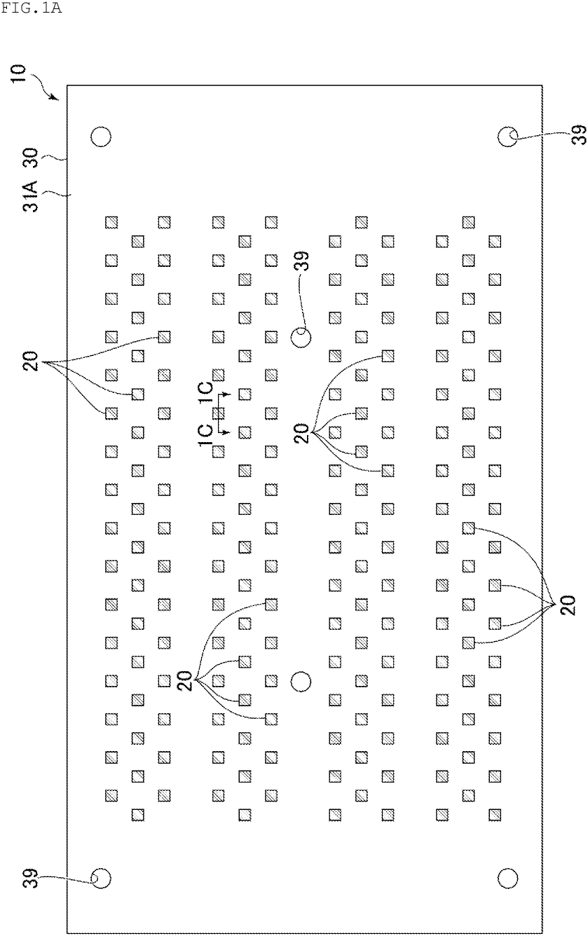

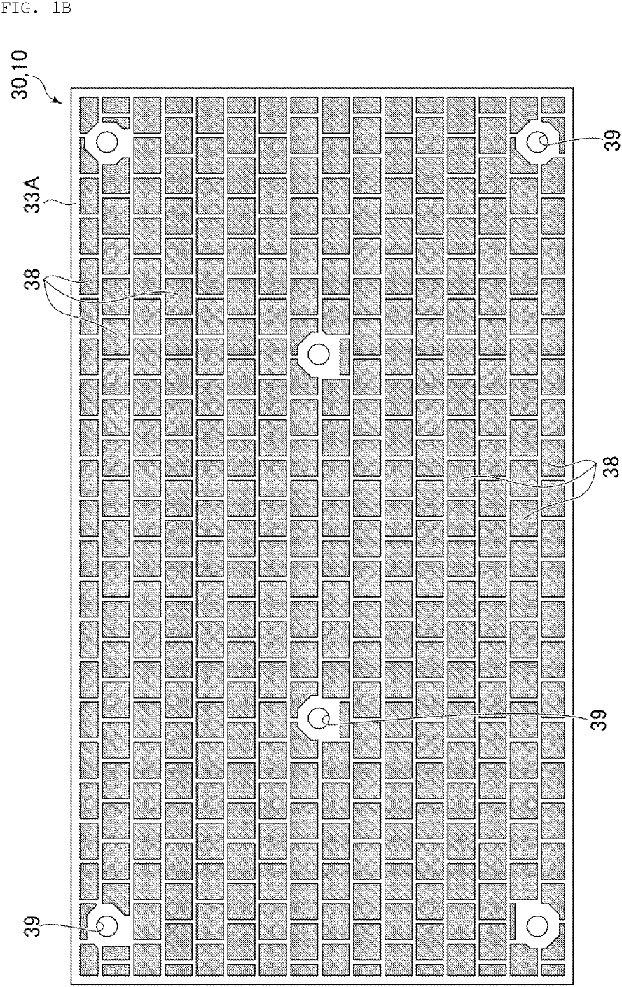

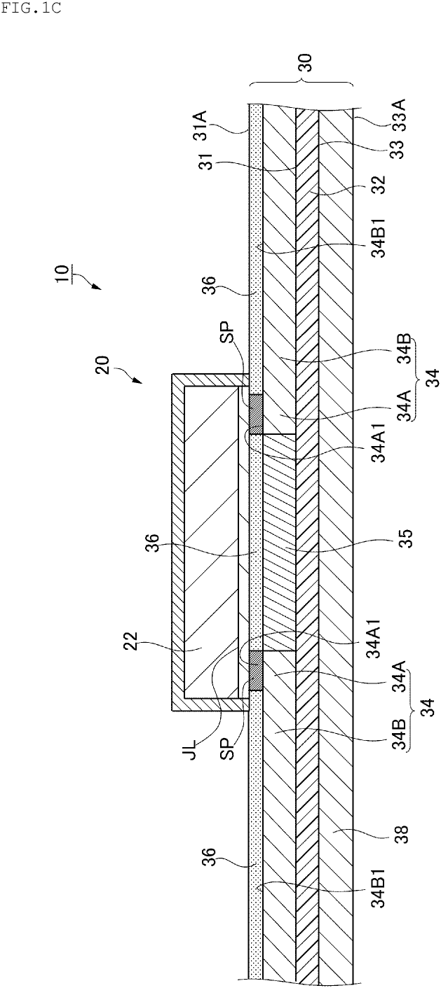

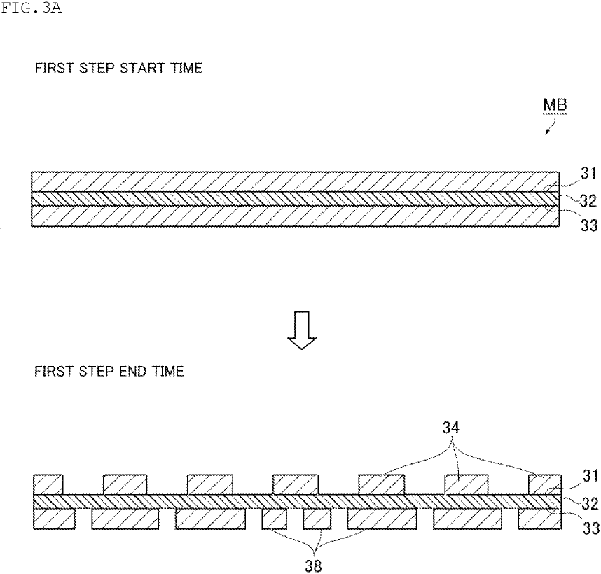

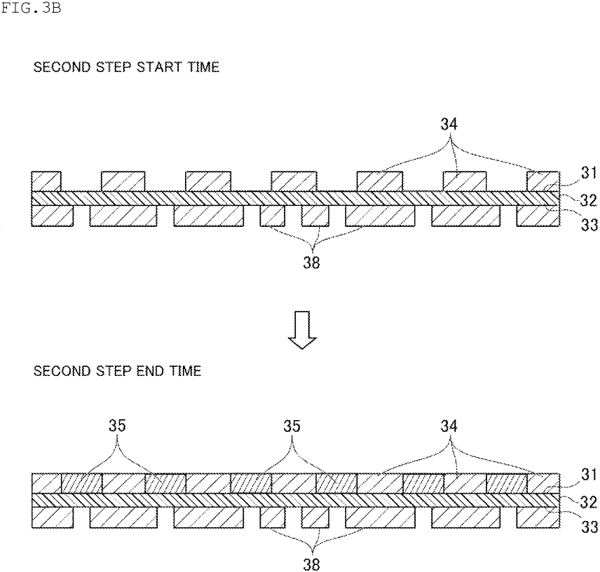

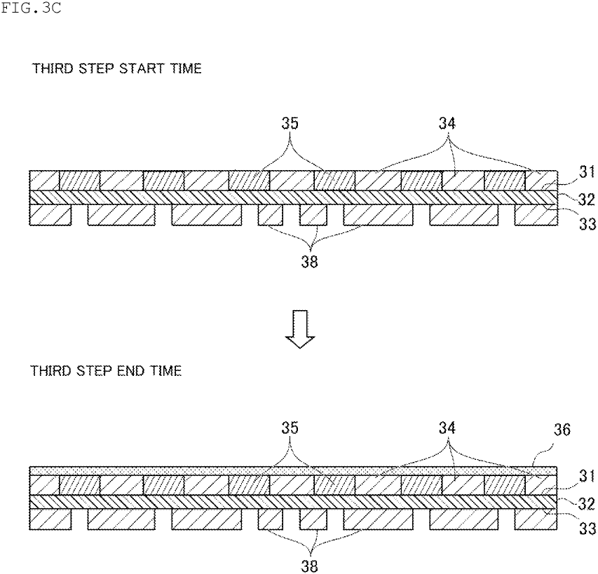

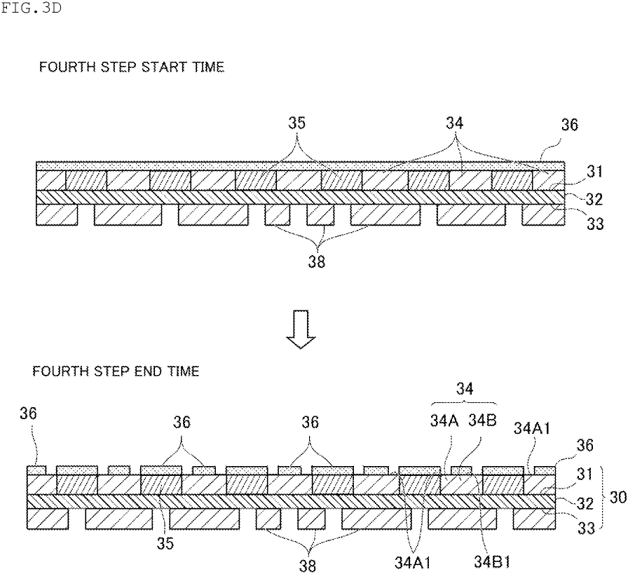

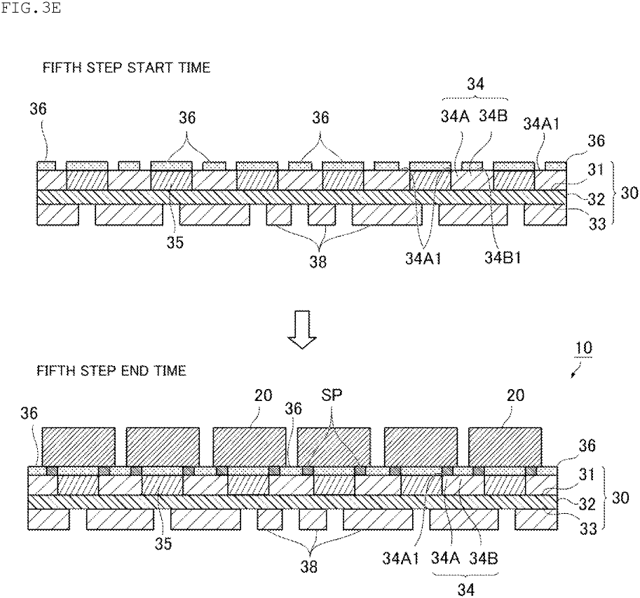

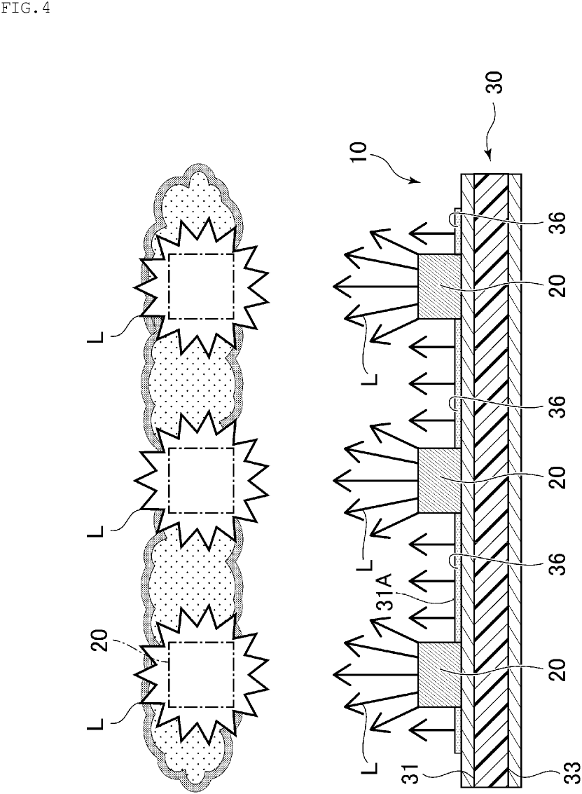

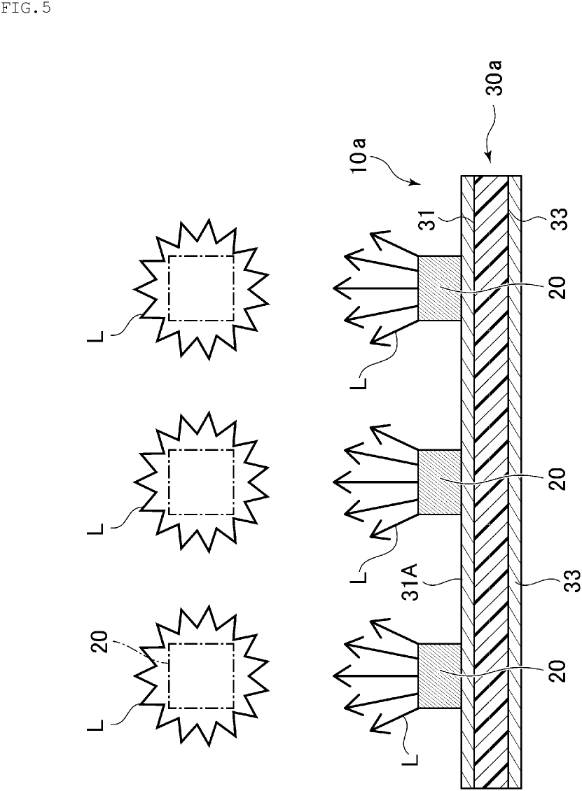

A description will be given below of the first embodiment with reference to FIG. 1A to FIG. 5. First, a description will be given of the configuration and functions of a light-emitting substrate 10 of the present embodiment with reference to FIG. 1A to FIG. 1C. Next, a description will be given of a method for manufacturing the light-emitting substrate 10 of the present embodiment with reference to FIG. 3A to FIG. 3E. Next, a description will be given of a light-emitting operation of the light-emitting substrate 10 of the present embodiment with reference to FIG. 4. Next, a description will be given of the effects of the present embodiment with reference to FIG. 4, FIG. 5, and the like.

Since a phosphor board 30 of the present embodiment is a constituent component of the light-emitting substrate 10 of the present embodiment, description thereof will be given in the description of the configuration and function of the light-emitting substrate 10 of the present embodiment.

### <Configuration and Function of Light-Emitting Substrate of First Embodiment>

FIG. 1A is a plan view of the light-emitting substrate 10 of the present embodiment (diagram viewed from a surface 31A side) and FIG. 1B is a bottom view of the light-emitting substrate 10 of the present embodiment (diagram viewed from a rear surface 33A side). FIG. 1C is a partial cross-sectional view of the light-emitting substrate 10 cut away on a 1C-1C cut line in FIG. 1A.

The light-emitting substrate 10 of the present embodiment is rectangular when viewed from the surface 31A side and the rear surface 33A side, as an example. In addition, the light-emitting substrate 10 of the present embodiment is provided with a plurality of the light-emitting elements 20, the phosphor board 30, and electronic components (not shown) such as connectors and driver ICs. That is, in the light-emitting substrate 10 of the present embodiment, the plurality of the light-emitting elements 20 and the electronic components described above are mounted on the phosphor board 30.

The light-emitting substrate 10 of the present embodiment has the function of emitting light when power is supplied from an external power source (not shown) through a connector. Therefore, the light-emitting substrate 10 of the present embodiment is used as a main optical component in, for example, a lighting device (not shown) or the like.

A detailed description will be given in the following description, but the basic configurations of the phosphor board 30 and the light-emitting substrate 10 of the present embodiment are as follows, respectively.

### Basic Configuration of Phosphor Board of Present Embodiment

The phosphor board 30 of the present embodiment is the phosphor board 30 on which at least one light-emitting element 20 is mounted and which is provided with an insulating layer 32 (an example of an insulating substrate), a circuit pattern layer 34 disposed on a surface 31 (an example of a surface) of the insulating layer 32 and bonded to the at least one light-emitting element 20, a phosphor layer 36 that is disposed on the surface 31 side of the insulating layer 32 and that includes a phosphor for which the emission peak wavelength is in the visible light region when the emitted light of the at least one light-emitting element 20 is used as excitation light, and a support layer 35 which is a layer that does not include the phosphor, which supports the phosphor layer 36, and which is disposed between the insulating layer 32 and the phosphor layer 36.

### Basic Configuration of Light-Emitting Substrate of Present Embodiment

In addition, the light-emitting substrate 10 of the present embodiment is provided with the phosphor board 30 having the basic configuration described above and the at least one light-emitting element 20.

### [Plurality of Light-Emitting Elements]

The plurality of the light-emitting elements 20 are each a Chip Scale Package (CSP) in which a flip chip LED 22 (referred to below as LED 22) is incorporated (refer to FIG. 1C), as an example. The plurality of the light-emitting elements 20 are mounted on the phosphor board 30 in a state of being regularly lined up over the entire surface 31A side of the phosphor board 30, as shown in FIG. 1A. The correlated color temperature of the light emitted by each of the light-emitting elements 20 is 3.018 K as an example. In the present embodiment, the phosphor board 30 is configured to dissipate (cool) the heat such that the temperature of the phosphor board 30 is kept, as an example, within 50° C. to 100° C. of room temperature during the light-emitting operation of the plurality of the light-emitting elements 20 by using a heat sink (not shown) or cooling fan (not shown) .

In addition, a junction level JL of the LED 22 is set to a position higher than the level of the surface of the phosphor layer 36. Here, to further explain the meaning of “to” used for numerical value ranges in the present specification, for example, “50° C. to 100° C.” means “50° C. or higher and 100° C. or lower”. That is, “to” as used for numerical value ranges in the present specification means “the portion described before ‘to’ or more and the portion described after ‘to’ or less”.

### [Phosphor Board]

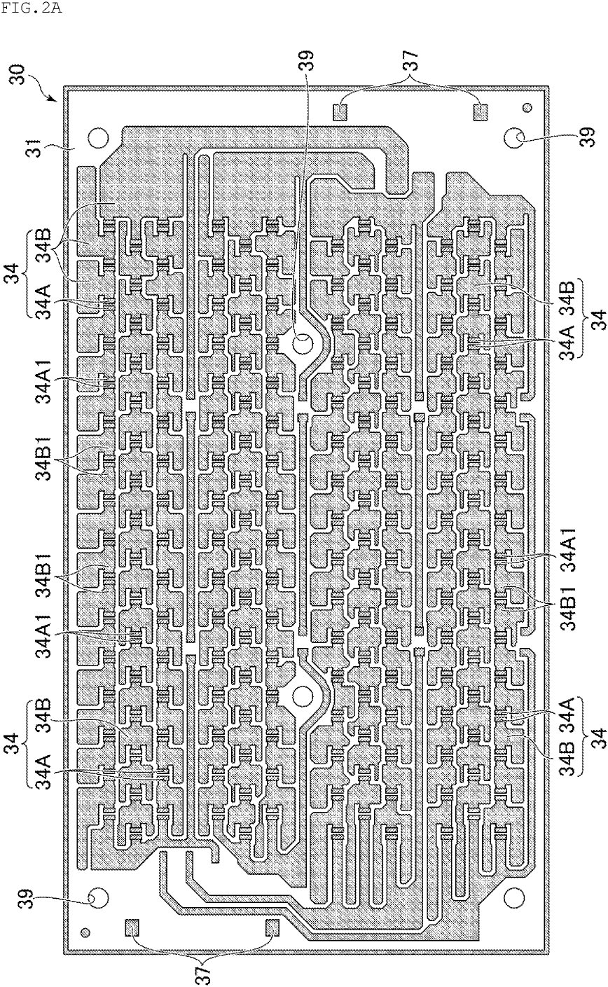

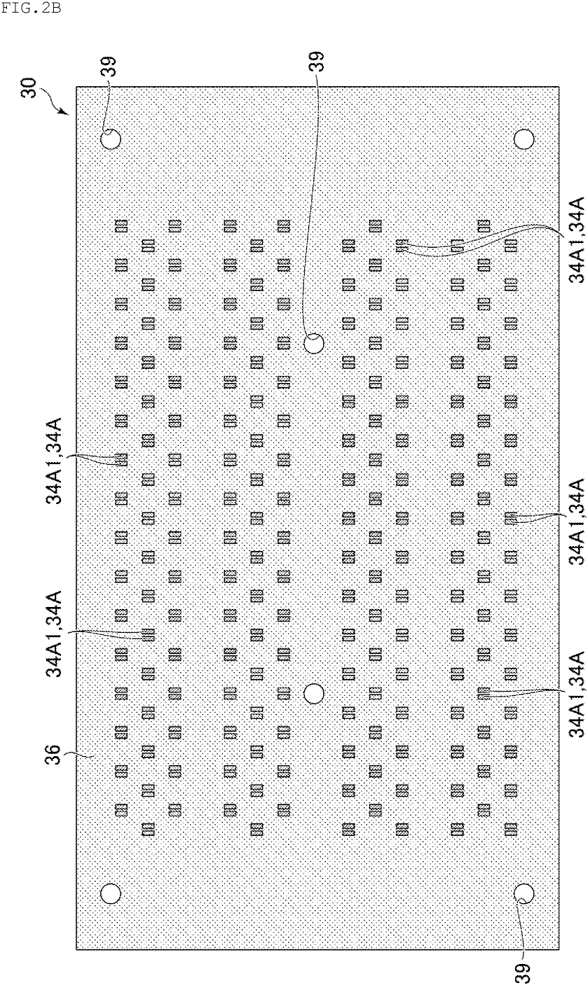

FIG. 2A is a plan view (diagram viewed from the surface 31A side) of the phosphor board 30 of the present embodiment, in which the support layer 35 and phosphor layer 36 are not shown. FIG. 2B is a plan view of the phosphor board 30 of the present embodiment (diagram viewed from the rear surface 33A side). The bottom view of the phosphor board 30 of the present embodiment is the same as the diagram in which the light-emitting substrate 10 is viewed from the rear surface 33A side. In addition, the partial cross-sectional view of the phosphor board 30 of the present embodiment is the same as the diagram in a case where the light-emitting element 20 is removed from the partial cross-sectional view of FIG. 1C. That is, the phosphor board 30 of the present embodiment is rectangular when viewed from the surface 31A side and the rear surface 33A side, as an example.

Although the range of a plurality of electrode pairs 34A, which will be described below, and wiring portions 34B, which are portions other than the plurality of the electrode pairs 34A, are illustrated in FIG. 2A, in practice, both are formed on the same plane (outer surface), thus, there is no boundary between the two in a diagram excluding the support layer 35 and the phosphor layer 36, as shown in FIG. 2A. However, FIG. 2A is a diagram in which the plurality of electrode pairs 34A and the wiring portions 34B are marked with reference numerals for convenience in order to clarify the positional relationship between the two.

The phosphor board 30 of the present embodiment is provided with the insulating layer 32, the circuit pattern layer 34, the support layer 35, the phosphor layer 36, and a rear surface pattern layer 38 (refer to FIG. 1B, FIG. 1C, FIG. 2A, and FIG. 2B). Although the support layer 35 and the phosphor layer 36 are not shown in FIG. 2A, the phosphor layer 36 is disposed on the surface 31 side of the insulating layer 32 as an example, as shown in FIG. 2B. Specifically, as an example, the phosphor layer 36 is disposed to cover the surface of the support layer 35 on the opposite side to the insulating layer 32 and a portion of the circuit pattern layer 34 other than the plurality of electrode pairs 34A described below, as shown in FIG. 1C. In addition, the support layer 35 is disposed between the insulating layer 32 and the phosphor layer 36, at a portion of the surface 31 of the insulating layer 32 other than the portion where the circuit pattern layer 34 is disposed (refer to FIG. 1C and FIG. 3E) .

In addition, through holes 39 are formed in the phosphor board 30 in a total of six locations, four near the four corners and two near the center, as shown in FIG. 1B and FIG. 2A. The six through holes 39 are used as position alignment holes when manufacturing the phosphor board 30 and the light-emitting substrate 10. In addition, the six through holes 39 are also used as screw holes for attachment to the (light-emitting) light fixture housing to ensure a heat drawing effect (to prevent substrate warpage and floating). As described below, the phosphor board 30 in the present embodiment is manufactured by processing, using etching or the like, a double-sided board (referred to below as a motherboard MB, refer to FIG. 3A) in which copper foil layers are provided on both surfaces of an insulating board. Examples of this motherboard MB include CS-3305Amanufactured by Risho Kogyo Co., Ltd.

### <Insulating Layer>

A description will be given below of the main features of the insulating layer 32 of the present embodiment. As described above, the shape is rectangular as viewed from the surface 31 side and a rear surface 33 side, as an example.

The material is an insulating material including bismaleimide resin and glass cloth, as an example.

The thickness is 100 µm, as an example.

The coefficients of thermal expansion (CTE) in the longitudinal direction and transverse direction are each 10 ppm/°C or less in a range of 50° C. to 100° C., as an example. In addition, from another viewpoint, the coefficients of thermal expansion (CTE) in the longitudinal direction and transverse direction are each 6 ppm/K, as an example. This value is almost equivalent (90% to 110%, that is, within ±10%) to that in the case of the light-emitting element 20 of the present embodiment.

The glass transition temperature is higher than 300° C., as an example.

The storage modulus is greater than 1.0 × 10¹⁰ Pa and less than 1.0 × 10¹¹ Pa in a range of 100° C. to 300° C., as an example.

As an example, the flexural moduli in the longitudinal direction and transverse direction are, 35 GPa and 34 GPa, respectively, under normal conditions.

The hot flexural moduli in the longitudinal direction and transverse direction are 19 GPa at 250° C., as an example. As an example, the water absorption is 0.13% in a case of being left for 24 hours in an environment at a temperature of 23° C. The dielectric constant is 4.6 at 1 MHz under normal conditions, as an example. The dielectric loss tangent is 0.010 at 1 MHz under normal conditions, as an example.

### <Circuit Pattern Layer>

The circuit pattern layer 34 of the present embodiment is a metal layer provided on the surface 31 of the insulating layer 32, as an example, a copper foil layer (a layer made of Cu), and is conductive with terminals 37 bonded to a connector (not shown). The circuit pattern layer 34 supplies power supplied from an external power source (not shown) through the connector to the plurality of the light-emitting elements 20 in the state of forming the light-emitting substrate 10. Therefore, a part of the circuit pattern layer 34 is a plurality of the electrode pairs 34A to which the plurality of the light-emitting elements 20 are respectively bonded. That is, the circuit pattern layer 34 is disposed on the surface 31 of the insulating layer 32 and connected to each of the light-emitting elements 20. In addition, from another view, the circuit pattern layer 34 is disposed on the surface 31 of the insulating layer 32 and is connected to each of the light-emitting elements 20 at bonding surfaces 34A1, which are the outer surfaces of each of the electrode pairs 34A.

In addition, as described above, since the plurality of the light-emitting elements 20 are regularly lined up over the entire surface 31 side of the insulating layer 32 (refer to FIG. 1A), the plurality of electrode pairs 34A are also regularly lined up over the entire surface 31 side (refer to FIG. 2A). Here, in the present specification, the portion of the circuit pattern layer 34 other than the plurality of electrode pairs 34A is referred to as the wiring portion 34B. In addition, the outer surface of the wiring portion 34B is referred to as a non-bonding surface 34B1 (the portion other than the bonding surfaces 34A1 on the outer surface of the circuit pattern layer 34). The non-bonding surface 34B1 is a portion of the circuit pattern layer 34 other than the portion bonded to all of the light-emitting elements 20.

Viewed from the surface 31 side, the ratio (the exclusive area of the circuit pattern layer 34) of the circuit pattern layer 34 with respect to the surface 31 of the insulating layer 32, is 60% or more of the surface 31 of the insulating layer 32, as an example (refer to FIG. 2A). In addition, in the present embodiment, the thickness of the circuit pattern layer 34 is 175 µm, as an example. However, in each diagram, the relationships between the thickness of the circuit pattern layer 34, the thickness of the insulating layer 32, the thickness of the phosphor layer 36, and the like do not have the dimensions shown.

### <Support Layer>

The support layer 35 of the present embodiment, as described above, is disposed on a portion of the surface 31 of the insulating layer 32 other than the portion where the circuit pattern layer 34 is disposed and supports a part of the phosphor layer 36 (refer to FIG. 1C and FIG. 3E) . Here, the part of the phosphor layer 36 supported by the support layer 35 means the portion of the phosphor layer 36 other than the portion disposed on the outer surface of the circuit pattern layer 34. As shown in FIG. 1C, FIG. 3E, and the like, as an example, the thickness of the support layer 35 is set to be the same as the thickness of the circuit pattern layer 34, but may be set to be thinner or conversely thicker, without being limited thereto.

The support layer 35 of the present embodiment, unlike the phosphor layer 36 described below, does not include a phosphor (an aggregate of a plurality of phosphor particles), but is an insulating layer that, as an example, includes a white pigment (an aggregate of a plurality of white particles) and a binder, in which the plurality of white particles are dispersed in the binder. In addition, the support layer 35 in the present embodiment is a monolayer structure, as an example. Here, as an example, the plurality of white particles are titanium oxide, but may also be calcium oxide or other white particles. In addition, the binder may be, for example, an epoxy-based binder, an acrylate-based binder, a silicone-based binder, or the like, as long as the binder has insulating properties equivalent to those of a binder included in a solder resist.

As described above, the support layer 35 is disposed between the insulating layer 32 and the phosphor layer 36 (refer to FIG. 1C, FIG. 3E, and the like). In addition, a description will be given of the technical significance of the support layer 35 including a white pigment in the description of the effects of the first embodiment below.

### <Phosphor Layer>

The phosphor layer 36 of the present embodiment is disposed on the surface (the upper side surface in the figure) of the support layer 35 on the opposite side to the insulating layer 32 and on the non-bonding surface 34B1 of the circuit pattern layer 34, as shown in FIG. 2B and FIG. 3E, as an example. From another view, the phosphor layer 36 is disposed so as to cover the surface 31 side of the insulating layer 32, leaving the support layer 35 and the electrode pairs 34A in the circuit pattern layer 34. In the present embodiment, viewed from the surface 31 side, the ratio of the phosphor layer 36 with respect to the surface 31 of the insulating layer 32 is 80% or more with respect to the area of the surface 31 of the insulating layer 32, as an example.

The outer side surface (outer surface) of the phosphor layer 36 in the thickness direction of the insulating layer 32 is positioned outside, in the thickness direction, of the outer side surface (outer surface) of the circuit pattern layer 34 in the thickness direction of the insulating layer 32 (refer to FIG. 1C and FIG. 3E). In addition, in the phosphor layer 36, the outer surfaces of the portions disposed on the support layer 35 and the outer surfaces of the portions disposed on the circuit pattern layer 34 are, as an example, positioned at the same height, that is, at the same position in the thickness direction of the insulating layer 32 (refer to FIG. 3E).

The phosphor layer 36 in the present embodiment is, for example, an insulating layer that includes a phosphor (an aggregate of a plurality of phosphor particles) and a binder, as described below, in which the plurality of phosphor particles are dispersed in the binder. The phosphor included in the phosphor layer 36 has the property of exciting the emitted light of each of the light-emitting elements 20 to be used as excitation light. Specifically, the phosphor of the present embodiment has a property in which the light emission peak wavelength is in the visible light region when the light emission of the light-emitting elements 20 is used as excitation light. The binder may be, for example, an epoxy-based binder, an acrylate-based binder, a silicone-based binder, or the like that has insulating properties equivalent to those of a binder included in a solder resist.

Here, in the present specification, the volume-based median diameter (D₅₀), as measured by a laser diffraction scattering method, of the plurality of phosphor particles included in the phosphor layer 36 is denoted as D1₅₀. In addition, the volume-based median diameter (D₅₀), as measured by a laser diffraction scattering method, of the plurality of white particles included in the support layer 35 is denoted as D2₅₀. Then, in the phosphor board 30 of the present embodiment, D1₅₀ and D2₅₀ have the relationship in (Equation 1), as an example.

$$0.8 \leq {\text{D2}}_{50} / {\text{D1}}_{50} \leq 1.2 \qquad \text{(Equation 1)}$$

That is, in the present embodiment, the median diameter (D₅₀) of the plurality of white particles forming the white pigment is set to be in a range of 80% or more and 120% or less with respect to the median diameter (D₅₀) of the plurality of phosphor particles forming the phosphor.

### (Specific Examples of Phosphor)

Here, the phosphor included in the phosphor layer 36 of the present embodiment is, as an example, at least one type of phosphor selected from the group consisting of α-type sialon phosphors containing Eu, β-type sialon phosphors containing Eu, CASN phosphors containing Eu, and SCASN phosphors containing Eu. The phosphors described above are examples in the present embodiment and phosphors other than the phosphors described above may also be used, such as YAG, LuAG, BOS, and other phosphors with visible light excitation.

The α-type sialon phosphors containing Eu are represented by general formula MₓEu_{y}Siₗ₂₋(ₘ₊ₙ)Al(ₘ₊ₙ)OₙN₁₆ ₙ. In the general formula described above, M is one type of element or more, including at least Ca, selected from the group consisting of Li, Mg, Ca, Y, and lanthanide elements (excluding La and Ce) and, when the valence of M is a, ax + 2y = m, where x is 0 < x ≤ 1.5, 0.3 ≤ m < 4.5, and 0 < n < 2.25.

The β-type sialon phosphor containing Eu is a phosphor in which divalent europium (Eu²⁺) is solid-dissolved as the light-emitting center in a β-type sialon represented by general formula: Si_{6-z}Al_{z}O_{z}N_{8-z} (z = 0.005 to 1).

In addition, examples of nitride phosphors include CASN phosphors containing Eu, SCASN phosphors containing Eu, and the like.

CASN phosphors containing Eu refer to, for example, a red phosphor represented by the formula CaAlSiN₃:Eu²⁺, in which Eu²⁺ is used as an activator, and a crystal formed of alkaline earth silicon nitride is set as the matrix. In the definition of CASN phosphors containing Eu in the present specification, SCASN phosphors containing Eu are excluded.

SCASN phosphors containing Eu refer to, for example, a red phosphor represented by formula (Sr,Ca)AlSiN₃:Eu²⁺, in which Eu²⁺ is used as an activator, and a crystal formed of alkaline earth silicon nitride is set as the matrix.

### <Rear Surface Pattern Layer>

The rear surface pattern layer 38 of the present embodiment is a metal layer provided on the rear surface 33 of the insulating layer 32, as an example, a copper foil layer (a layer made of Cu) .

As shown in FIG. 1B, the rear surface pattern layer 38 is a layer in which a plurality of rows of rectangular portions which are lined up in straight lines in the longitudinal direction of the insulating layer 32 are lined up in a plurality of rows in the short direction. Two adjacent rows are disposed in a state of being out of phase with each other in the longitudinal direction. In addition, the rear surface pattern layer 38 is an independent floating layer, as an example.

As an example, the rear surface pattern layer 38 overlaps 80% or more of the region of the circuit pattern layer 34 disposed on the surface 31 as viewed from the thickness direction of the insulating layer 32.

The foregoing was a description of the configuration of the light-emitting substrate 10 and the phosphor board 30 of the present embodiment.

### <Method for Manufacturing Light-Emitting Substrate of First Embodiment>

Next, a description will be given of the method for manufacturing the light-emitting substrate 10 of the present embodiment with reference to FIG. 3A to FIG. 3E. The method for manufacturing the light-emitting substrate 10 of the present embodiment includes a first step, a second step, a third step, a fourth step, and a fifth step, and each step is performed in the described order.

A detailed description will be given in the following description, but the basic configurations of the method for manufacturing the phosphor board 30 and the method for manufacturing the light-emitting substrate 10 of the present embodiment, are as follows, respectively.

### Basic Configuration of Method for Manufacturing Phosphor Board

The method for manufacturing the phosphor board 30 of the present embodiment includes a first step (circuit pattern layer forming step) of forming the circuit pattern layer 34 to be bonded to at least one of the light-emitting elements 20 on the surface 31 (an example of one surface) of the insulating layer 32 (an example of an insulating substrate), a third step (phosphor layer forming step) of forming, on the surface 31 side of the insulating layer 32, the phosphor layer 36 including a phosphor in which the emission peak wavelength is in the visible light region when the emitted light of the at least one light-emitting element 20 is used as excitation light, and a second step (support layer forming step) of forming the support layer 35, which is a layer that does not include the phosphor and which supports the phosphor layer 36, between the insulating layer 32 and the phosphor layer 36, in which, in the phosphor layer forming step, the phosphor layer 36 is laminated on the support layer 35.

### Basic Configuration of Method for Manufacturing Light-Emitting Substrate

The method for manufacturing the light-emitting substrate 10 of the present embodiment includes the method for manufacturing the phosphor board 30 of the present embodiment described above and a fifth step (bonding step) of bonding at least one of the light-emitting elements 20 to the circuit pattern layer 34.

### [First Step]

FIG. 3A is a diagram showing the start time and end time of the first step. The first step (an example of a circuit pattern layer forming step) is a step of forming the circuit pattern layer 34 on the surface 31 side of the motherboard MB (that is, the insulating layer 32) and the rear surface pattern layer 38 on the rear surface 33 side. This step is performed, for example, by etching using a mask pattern (not shown).

### [Second Step]

FIG. 3B is a diagram showing the start time and end time of the second step. The second step (an example of a support layer forming step) is a step of forming the support layer 35, which is a layer that does not include the phosphor and which supports the phosphor layer 36 formed in the third step, between the insulating layer 32 and the phosphor layer 36 formed in the third step. In this step, white paint (not shown) is coated on the surface 31 of the insulating layer 32 in portions other than the portion where the circuit pattern layer 34 is disposed, to form the support layer 35. Here, the white paint is a paint in which a solvent is added to a white pigment (aggregate of a plurality of white particles) and a binder that form the support layer 35 and the layer of the coated white paint becomes the support layer 35 after curing. As a result, when this step is completed, a layer with a monolayer structure including a white pigment is formed as the support layer 35. In addition, in this step, the white paint is coated such that the thickness of the white paint layer after curing, that is, the thickness of the support layer 35, is thinner than the thickness of the circuit pattern layer 34.

The support layer 35 formed by this step may be formed by coating the white paint once or a plurality of times in the thickness direction of the insulating layer 32.

### [Third Step]

FIG. 3C is a diagram showing the start time and end time of the third step. The third step (an example of the phosphor layer forming step) is a step of coating phosphor paint (not shown) on the surface 31 side of the insulating layer 32 to form the phosphor layer 36. Specifically, in this step, phosphor paint is coated on the outer surface of the support layer 35 formed in the second step and the outer surface of the circuit pattern layer 34. That is, in this step, a part of the phosphor layer 36 is laminated on the support layer 35. In addition, in this step, the phosphor layer 36 is formed on the outer surface of the support layer 35 and the outer surface of the circuit pattern layer 34 and, as an example, the phosphor layer 36 is formed such that the outer surface thereof is flat. In addition, in this step, the phosphor layer 36 is formed such that the thickness of the portion of the phosphor layer 36 that is disposed on the outer surface of the support layer 35 is thinner than the thickness of the support layer 35.

### [Fourth Step]

FIG. 3D is a diagram showing the start time and end time of the fourth step. The fourth step is a step of removing a part of the phosphor layer 36 to expose all of the bonding surfaces 34A1 of the circuit pattern layer 34. Here, in a case where the binder of the phosphor paint is, for example, a thermosetting resin, the portions on each of the bonding surfaces 34A1 in the phosphor layer 36 are selectively irradiated with a laser beam using a two-dimensional laser processing device (not shown) after the phosphor paint is cured by heating. As a result, the portions on each of the bonding surfaces 34A1 in the phosphor layer 36 are ablated to expose each of the bonding surfaces 34A1. As a result of the above, the phosphor board 30 of the present embodiment is manufactured.

In addition to the method described above, this step may be performed by, for example, the following method. In a case where the phosphor paint binder is, for example, a UV curable resin (photosensitive resin), a mask pattern is applied to the portion (paint opening portion) overlapping each of the bonding surfaces 34A1 and exposed to UV light, the portions other than the mask pattern are UV cured, and the unexposed portions (uncured portions) are removed with a resin removal solution to expose each of the bonding surfaces 34A1. Thereafter, generally, after-curing is performed by the application of heat (photo-developing method). In addition, instead of the third step and fourth step, the phosphor layer 36 may be formed by screen-printing using a screen mask (not shown) in which opening portions are set in advance (screen-printing method). In such a case, the phosphor paint opening portions in the portions overlapping the bonding surfaces 34A1 in the screen mask may be root-clogged.

When this step is completed, the phosphor board 30 is manufactured.

### [Fifth Step]

FIG. 3E is a diagram showing the start time and end time of the fifth step. The fifth step (an example of a bonding step) is a step of mounting a plurality of the light-emitting elements 20 on the phosphor board 30. In this step, solder paste SP is printed on each of the bonding surfaces 34A1 exposed by removing the phosphor layer 36 of the phosphor board 30 in a concave shape, and the solder paste SP is melted in a state where each electrode of the plurality of the light-emitting elements 20 is aligned on each of the bonding surfaces 34A1. Thereafter, when the solder paste SP cools and solidifies, each of the light-emitting elements 20 is bonded to each electrode pair 34A (each of the bonding surfaces 34A1). This step is performed by a reflow step, as an example.

When this step is completed, the light-emitting substrate 10 is manufactured.

The foregoing was a description of the method for manufacturing the light-emitting substrate 10 of the present embodiment.

### <Light-Emitting Operation of Light-Emitting Substrate of First Embodiment>

Next, a description will be given of the light-emitting operation of the light-emitting substrate 10 of the present embodiment with reference to FIG. 1C and FIG. 4. Here, FIG. 4 is a diagram for illustrating the light-emitting operation of the light-emitting substrate 10 of the present embodiment.

First, when an activation switch (not shown) that activates the plurality of the light-emitting elements 20 is turned on, power supply is started from an external power source (not shown) through a connector (not shown) to the circuit pattern layer 34, the plurality of the light-emitting elements 20 scatter and emit light L in a radial manner and a part of the light L reaches the surface 31A of the phosphor board 30. More specifically, the light emission in the LEDs 22 of the light-emitting elements 20 is carried out at the junction level JL of the LEDs 22 (that is, the PN bonding surface) (refer to FIG. 1C).

A description will be given below of the behavior of the light L, separated into the travel directions of the emitted light L.

A part of the light L emitted from each of the light-emitting elements 20 is emitted outside without being incident to the phosphor layer 36. In such a case, the wavelength of the light L remains the same as the wavelength of the light L when emitted from each of the light-emitting elements 20.

In addition, the light of the LED 22 itself in a part of the light L emitted from each of the light-emitting elements 20 is incident to the phosphor layer 36. Here, the “light of the LED 22 itself in a part of the light L” means the light in the emitted light L that is not color-converted by the phosphor of each of the light-emitting elements 20 (the CSP itself), that is, the light of the LED 22 itself (as an example, blue light (with a wavelength in the vicinity of 470 nm)).

When the light L of the LED 22 itself hits the phosphor dispersed in the phosphor layer 36, the phosphor is excited and emits excitation light. Here, the reason why the phosphors are excited is because phosphors (visible light excitation phosphors) having an excitation peak in blue light are used for the phosphors dispersed in the phosphor layer 36.

Accordingly, some of the energy of the light L is used to excite the phosphors and the light L loses some energy. As a result, the wavelength of the light L is converted (wavelength conversion is performed). For example, depending on the type of phosphor in the phosphor layer 36 (for example, in a case where red CASN is used as the phosphor), the wavelength of the light L becomes longer (for example, 650 nm or the like).

In addition, the excitation light in the phosphor layer 36 may be emitted from the phosphor layer 36 as it is, but a part of the excitation light is directed to the circuit pattern layer 34 on the lower side and a part of the excitation light is directed to the support layer 35 on the lower side.

The excitation light directed to the circuit pattern layer 34 is then emitted to the outside due to reflection from the circuit pattern layer 34. As above, in a case where the wavelength of the excitation light by the phosphor is 600 nm or longer, a reflection effect is expected even when the circuit pattern layer 34 is Cu. Depending on the type of phosphor in the phosphor layer 36, the wavelength of the light L may differ from the example described above, but in any case, the light L is subjected to wavelength conversion. For example, in a case where the wavelength of the excitation light is less than 600 nm, a reflection effect is expected when the circuit pattern layer 34 or the surface thereof is, for example, Ag (plated) . In contrast, the excitation light directed to the support layer 35 is emitted to the outside due to reflection from the white pigment of the support layer 35. In such a case, it is possible to improve the reflection effect in the entire wavelength range of visible light.

As described above, the light L emitted by each of the light-emitting elements 20 (the light L emitted in a radial manner by each of the light-emitting elements 20) is respectively irradiated to the outside together with the excitation light described above through a plurality of optical paths as described above. Therefore, in a case where the light emission wavelength of the phosphor included in the phosphor layer 36 and the light emission wavelength of the phosphor sealing (or covering) the LED 22 in the light-emitting element 20 (CSP) are different, the light-emitting substrate 10 of the present embodiment irradiates, together with the excitation light described above, a bundle of the light L when each of the light-emitting elements 20 carries out emission, as a bundle of the light L including the light L of a wavelength different from the wavelength of the light L emitted by each of the light-emitting elements 20. For example, the light-emitting substrate 10 of the present embodiment irradiates a composite light of the light (wavelength) emitted by the light-emitting element 20 and the light (wavelength) emitted from the phosphor layer 36.

In contrast, in a case where the light emission wavelength of the phosphor included in the phosphor layer 36 and the light emission wavelength of the phosphor sealing (or covering) the LED 22 in the light-emitting element 20 (CSP) are the same (in a case of the same correlated color temperature), the light-emitting substrate 10 of the present embodiment irradiates, together with the excitation light described above, a bundle of the light L when each of the light-emitting elements 20 carries out emission as a bundle of the light L including the light L of the same wavelength as the wavelength of the light L when each of the light-emitting elements 20 carries out emission.

The foregoing was a description of the light-emitting operation of the light-emitting substrate 10 of the present embodiment.

### <Effects of First Embodiment>

Next, a description will be given below of the effects of the present embodiment with reference to the drawings.

### [First Effect]

A description will be given of the first effect by comparing the present embodiment with a comparative form (refer to FIG. 5) described below. Here, in the description of the comparative form, in a case where the same constituent components and the like as in the present embodiments are used, the same names, reference numerals, and the like as in the case of the present embodiment will be used for those constituent components and the like. FIG. 5 is a diagram for illustrating the light-emitting operation of a light-emitting substrate 10a of the comparative form. The light-emitting substrate 10a (a substrate 30a on which the plurality of the light-emitting elements 20 are mounted) of the comparative form has the same configuration as the light-emitting substrate 10 (the phosphor board 30) of the present embodiment except for the point that the phosphor layer 36 is not provided.

In the case of the light-emitting substrate 10a of the comparative form, the light L emitted from each of the light-emitting elements 20 and incident to the surface 31A of the substrate 30a is reflected or scattered without wavelength conversion. Therefore, in the case of the substrate 30a of the comparative form, it is not possible to adjust the light to an emitted light color different from the light emitted by the light-emitting elements 20 in a case where the light-emitting elements 20 are mounted thereon. That is, in the case of the light-emitting substrate 10a of the comparative form, it is not possible to adjust the light to an emitted light color different from the light emitted by the light-emitting elements 20.

In contrast, in the case of the present embodiment, viewed from the thickness direction of the insulating layer 32, the phosphor layer 36 is disposed on the surface 31 of the insulating layer 32 and at the periphery of each of the bonding surfaces 34A1 with each of the light-emitting elements 20. Therefore, a part of the light L emitted in a radial manner from each of the light-emitting elements 20 is incident to the phosphor layer 36 to be wavelength-converted by the phosphor layer 36 and irradiated to the outside. In such a case, a part of the light L emitted in a radial manner from each of the light-emitting elements 20 is incident to the phosphor layer 36 to excite the phosphor included in the phosphor layer 36 and generate excitation light.

Accordingly, according to the phosphor board 30 of the present embodiment, in a case where the light-emitting elements 20 are mounted, it is possible to adjust the light L emitted from the phosphor board 30 to be light emitted with a color different from the light L emitted by the light-emitting elements 20. Accordingly, according to the light-emitting substrate 10 of the present embodiment, it is possible to adjust the light L emitted from the phosphor board 30 to light L with an emitted light color different from the light L emitted by the light-emitting element 20. From another viewpoint, according to the light-emitting substrate 10 of the present embodiment, it is possible to emit the light L with an emitted light color different from the light L emitted by the light-emitting elements 20 to the outside.

### [Second Effect]

A description will be given of the second effect by comparing the present embodiment with the comparative form (refer to FIG. 5) . In the case of the comparative form, as shown in FIG. 5, spots are generated in the light L radiated to the outside due to the spacing of the arrangement of each of the light-emitting elements 20. Here, the larger the spots of the light L are, the greater the glare is.

In contrast, as shown in FIG. 2B, on the surface 31A side of the phosphor board 30 of the present embodiment, the phosphor layer 36 is entirely provided on the portions other than each of the bonding surfaces 34A1. Therefore, in the light-emitting substrate 10 of the present embodiment, excitation light is also emitted from the periphery (the periphery of each of the light-emitting elements 20) of each of the bonding surfaces 34A1.

Accordingly, according to the present embodiment, it is possible to reduce glare compared to the comparative form.

This effect is more effective in a case where the phosphor layer 36 is provided over the entire surface of the insulating layer 32, specifically, in a case where the ratio of the phosphor layer 36 with respect to the surface 31 of the insulating layer 32 is 80% or more of the surface 31, viewed from the surface 31 side.

### [Third Effect]

In the case of the present embodiment, a part of the phosphor layer 36 is supported by the support layer 35 (refer to FIG. 1C and FIG. 3E). Here, the white pigment forming the support layer 35 is cheaper than the phosphor forming the phosphor layer 36 and thus the white paint for forming the support layer 35 is cheaper than the phosphor paint.

Accordingly, the phosphor board 30 of the present embodiment is cheaper than in a case where the support layer 35 is formed by the phosphor layer 36. Accordingly, in the method for manufacturing the phosphor board 30 of the present embodiment, the cost of manufacturing the phosphor board 30 is cheaper than in a method for manufacturing a phosphor board in which the support layer 35 is formed by the phosphor layer 36.

In the case of the light-emitting substrate 10 of the present embodiment, considering the influence of the heat generated when the plurality of LEDs 22 emit light and the heat generated by the phosphor layer 36 that undergoes excitation, for example, the thickness of the circuit pattern layer 34 is set to be thicker than a normal circuit board (as an example, 175 µm). On top of that, in the case of the present embodiment, the outer surface of the phosphor layer 36 is set outside the outer surface of the circuit pattern layer 34 in the thickness direction of the insulating layer 32. This effect is noticeable in the case of the above configuration as in the present embodiment.

### [Fourth Effect]

In addition, in the case of the present embodiment, the thickness of the phosphor layer 36 is thinner than the thickness of the support layer 35, as described above.

Accordingly, the phosphor board 30 of the present embodiment is cheaper than in a case where the thickness of the phosphor layer 36 is the thickness of the support layer 35 or less. Accordingly, in the method for manufacturing the phosphor board 30 of the present embodiment, the manufacturing cost of the phosphor board 30 is cheaper than in a method for manufacturing a phosphor board in which the thickness of the phosphor layer 36 is the thickness of the support layer 35 or less.

### [Fifth Effect]

In the case of the present embodiment, as described above, the support layer 35 includes a white pigment. Therefore, according to the present embodiment, it is possible to increase the reflective effect of the entire wavelength range of excitation light, which is set to be visible light.

### [Sixth Effect]

In the case of the present embodiment, D1₅₀ and D2₅₀ have the relationship in (Equation 1).

$$0.8 \leq {\text{D2}}_{50} / {\text{D1}}_{50} \leq 1.2 \qquad \text{(Equation 1)}$$

With the above configuration, the difference in median diameters of the fine particles (plurality of phosphor particles and plurality of white particles) in each layer is set to be comparatively small.

Accordingly, the phosphor board 30 of the present embodiment has a smaller difference in the coefficient of thermal expansion (CTE) between the support layer 35 and the phosphor layer 36, resulting in reduced stress being generated at the interface thereof.

The foregoing was a description of the effects of the present embodiment.

In addition, the foregoing was a description of the first embodiment.

### Second Embodiment

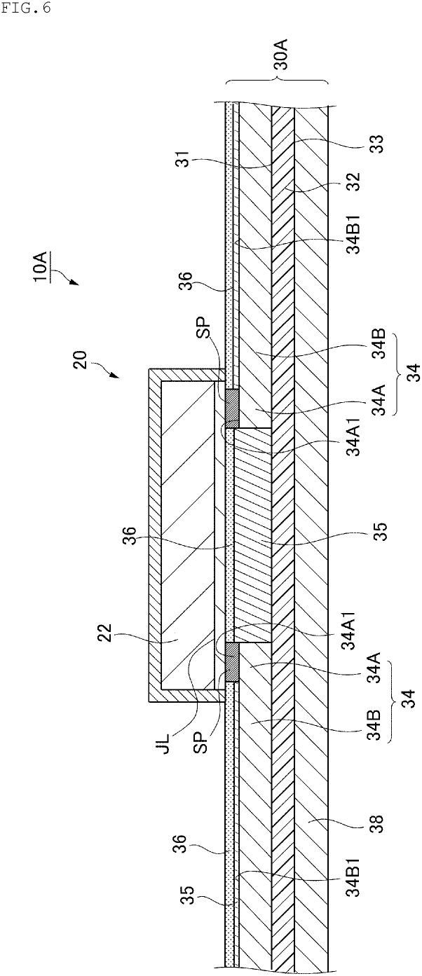

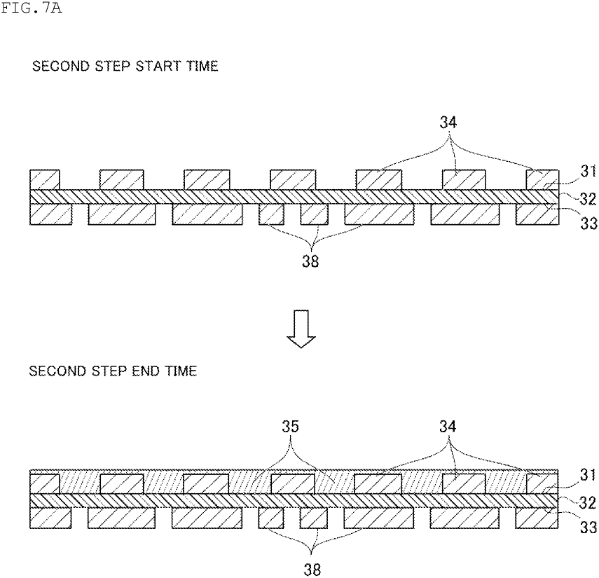

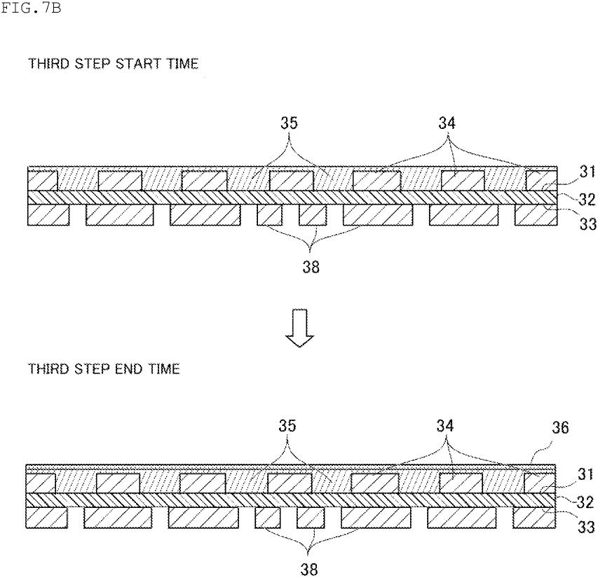

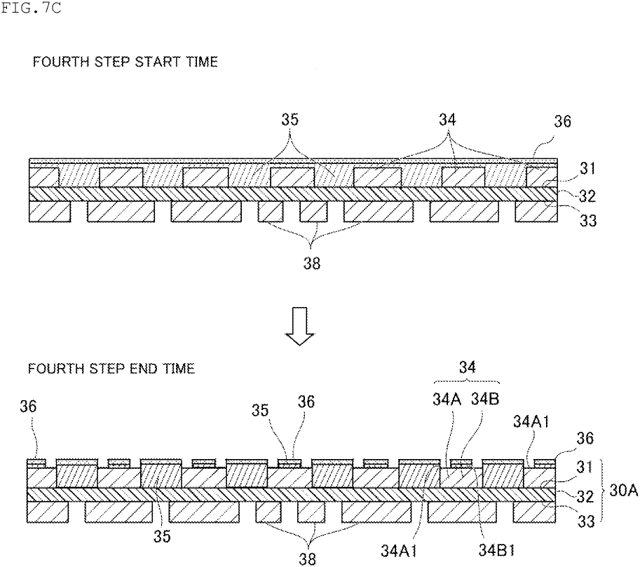

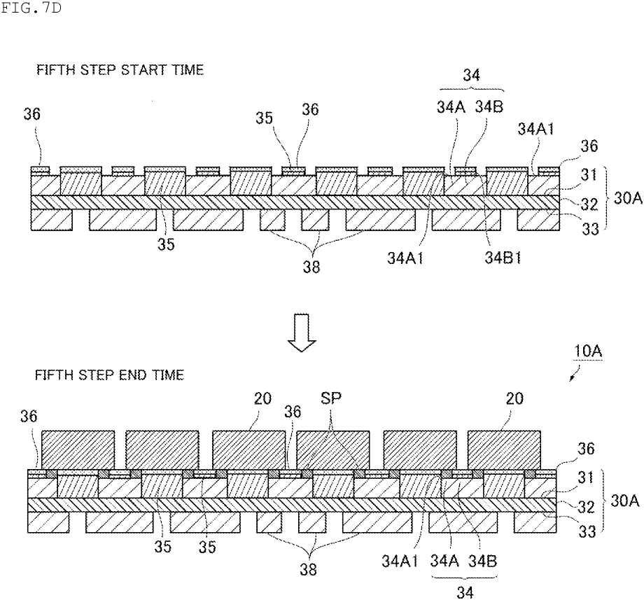

Next, a description will be given of the second embodiment with reference to FIG. 6 and FIG. 7A to FIG. 7D. A description will be given below of only those parts of the present embodiment that differ from the first embodiment (refer to FIG. 1C, FIG. 3A to FIG. 3E, and the like).

### <Configuration of Second Embodiment>

A phosphor board 30A (refer to FIG. 6) of the present embodiment differs from the phosphor board 30 (refer to FIG. 1C) of the first embodiment in the point that the support layer 35 is also disposed on the non-bonding surface 34B1 of the circuit pattern layer 34. The support layer 35 is formed on a part of the surface 31 of the insulating layer 32 and the non-bonding surface 34B1 of the circuit pattern layer 34 and the outer surface thereof is flat.

### <Method for Manufacturing Phosphor Board of Second Embodiment>

Next, a description will be given of a method for manufacturing the phosphor board 30A of the present embodiment with reference to FIG. 7A to FIG. 7D. A method for manufacturing a light-emitting substrate 10A of the present embodiment includes a first step, a second step, a third step, a fourth step, and a fifth step, and each step is performed in the described order.

### [First Step]

This step is the same as in the case of the first embodiment (refer to FIG. 3A).

### [Second Step]

FIG. 7A is a diagram showing the start time and end time of the second step. The second step (an example of a support layer forming step) is a step of forming the support layer 35, which is a layer that does not include the phosphor and which supports the phosphor layer 36 formed in the third step, between the insulating layer 32 and the phosphor layer 36 formed in the third step. In this step, white paint (not shown, the same as in the case of the first embodiment) is coated on the surface 31 of the insulating layer 32 on the portions other than the portions where the circuit pattern layer 34 is disposed and on the entire outer surface of the circuit pattern layer 34, and the support layer 35 is formed such that the outer surface is flat across the entire area. When this step is completed, a layer with a monolayer structure including a white pigment is formed as the support layer 35.

### [Third Step]

FIG. 7B is a diagram showing the start time and end time of the third step. The third step (an example of the phosphor layer forming step) is a step of coating phosphor paint (not shown) on the surface 31 side of the insulating layer 32 to form the phosphor layer 36. Specifically, in this step, the phosphor paint is coated on the outer surface of the support layer 35 formed in the second step.

### [Fourth Step]

FIG. 7C is a diagram showing the start time and end time of the fourth step. The fourth step is a step in which a part of the phosphor layer 36 and a part of the support layer 35 are removed to expose all of the bonding surfaces 34A1 of the circuit pattern layer 34. The step of exposing the bonding surfaces 34A1 is performed in the same step as in the first embodiment, using a method of removal by laser beam irradiation or a method such as a photo printing method or a screen-printing method selected as appropriate. When this step is completed, the phosphor board 30A is manufactured.

### [Fifth Step]

FIG. 7D is a diagram showing the start time and end time of the fifth step. The fifth step (an example of a bonding step) is a step of mounting the plurality of the light-emitting elements 20 on the phosphor board 30. This step is the same as the step of the first embodiment illustrated in FIG. 3E, where solder paste SP is printed on each of the bonding surfaces 34A1 by a reflow process and the plurality of the light-emitting elements 20 are mounted and bonded on each of the bonding surfaces 34A1. When this step is completed, the light-emitting substrate 10A is manufactured.

The foregoing was a description of the method for manufacturing the light-emitting substrate 10A of the present embodiment.

### <Light-Emitting Operation of Light-Emitting Substrate of Second Embodiment>

Next, a description will be given of a light-emitting operation of the light-emitting substrate 10A of the present embodiment. The light-emitting operation of the light-emitting substrate 10A of the present embodiment is basically the same as the case of the first embodiment. However, unlike the case of the first embodiment, in the light-emitting substrate 10A of the present embodiment, the non-bonding surface 34B1 of the circuit pattern layer 34 is covered with the support layer 35. Therefore, in the excitation light in the phosphor layer 36, the excitation light directed toward the circuit pattern layer 34 is reflected by the support layer 35.

The foregoing was a description of the light-emitting operation of the light-emitting substrate 10A of the present embodiment.

### <Effects of Second Embodiment>

In the case of the present embodiment, unlike the case of the first embodiment, the entire region of the phosphor layer 36 is supported by the support layer 35 including a white pigment. Therefore, according to the present embodiment, in the entire region of the phosphor layer 36, the reflection effect of the entire wavelength region of the excitation light, which is set to be visible light, may be improved.

Other effects of the present embodiment are the same as those of the case of the first embodiment.

The foregoing was a description of the effects of the present embodiment.

In addition, the foregoing was a description of the second embodiment.

### Third Embodiment

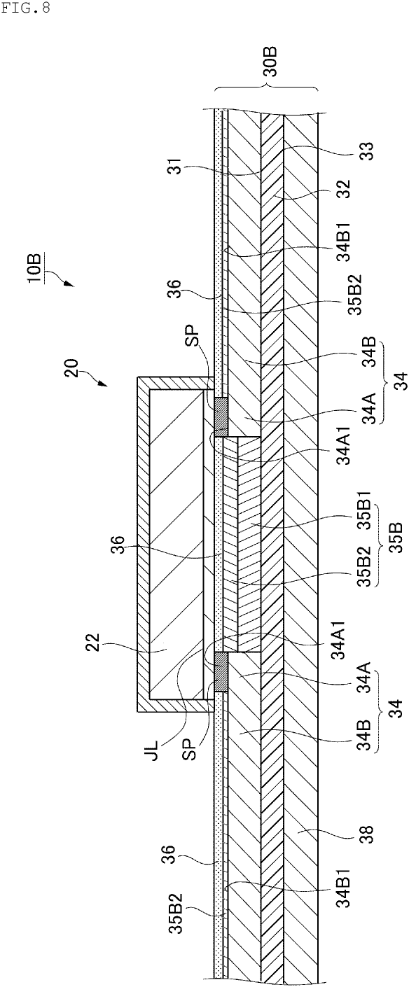

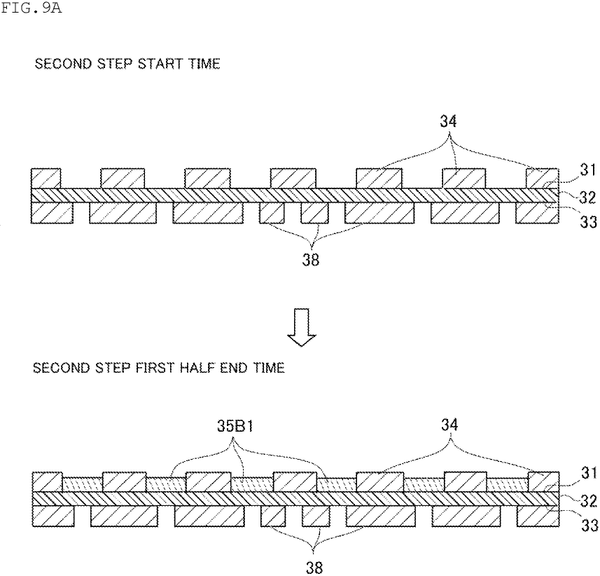

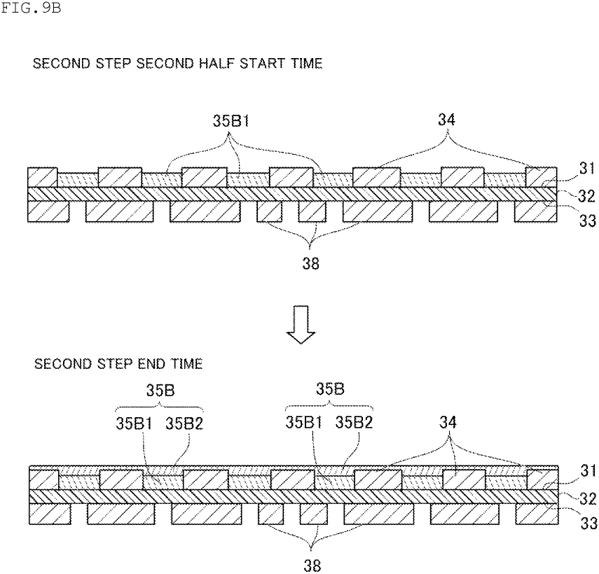

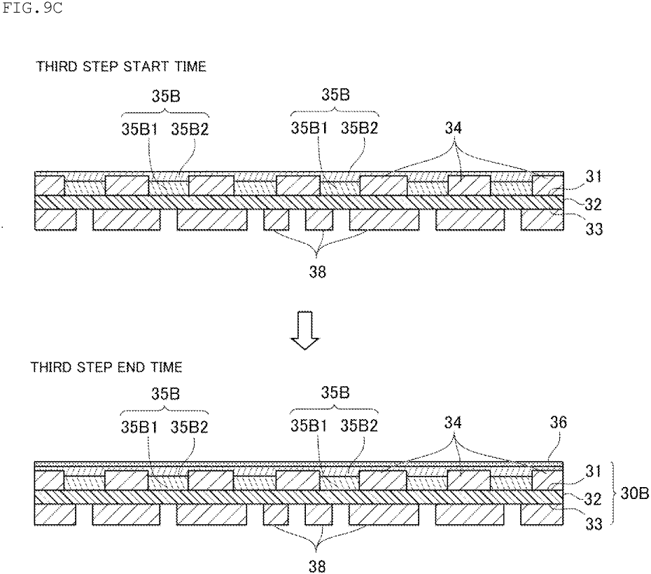

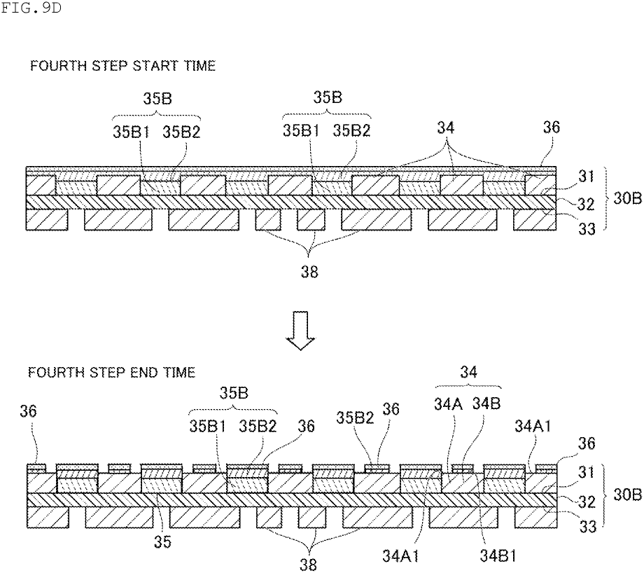

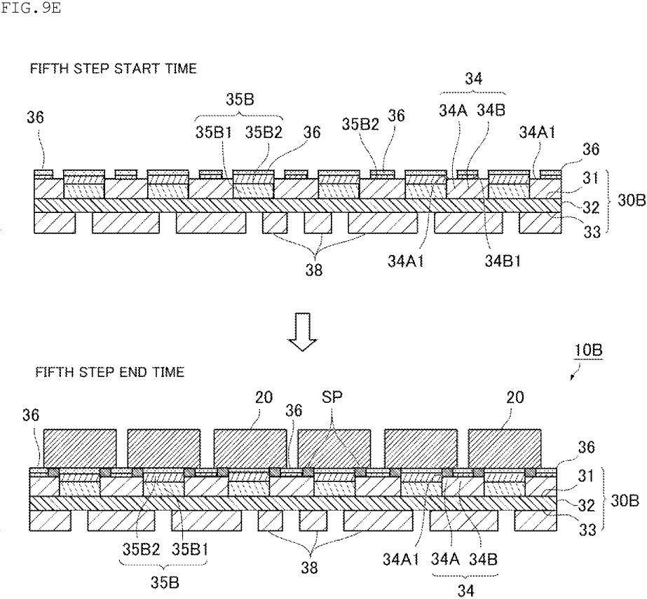

Next, a description will be given of the third embodiment with reference to FIG. 8 and FIG. 9A to FIG. 9E. A description will be given below of only those portions of the present embodiment that differ from the second embodiment (refer to FIG. 6 and the like).

### <Configuration of Third Embodiment>

A phosphor board 30B (refer to FIG. 8) of the present embodiment differs from the phosphor board 30A (refer to FIG. 6) of the second embodiment in that a support layer 35B has a multilayer structure. Specifically, the support layer 35B of the present embodiment is formed of a first layer 35B1 (an example of a base layer) and a second layer 35B2 (an example of an adjacent layer). The first layer 35B1 is disposed on a portion of the surface 31 of the insulating layer 32 other than the portion where the circuit pattern layer 34 is formed. The thickness of the first layer 35B1 is thinner than the thickness of the circuit pattern layer 34. The second layer 35B2 is disposed on the first layer 35B1 and the non-bonding surface 34B1 of the circuit pattern layer 34. Here, the first layer 35B1 is a layer that does not include a white pigment and is, as an example, a layer in which white pigment is excluded from the support layer 35 of the first embodiment and the second embodiment. In addition, a part of the second layer 35B2 is disposed between the first layer 35B1 and the phosphor layer 36 while other parts are disposed between the circuit pattern layer 34 and the phosphor layer 36. That is, the second layer 35B2 is a layer adjacent to the phosphor layer 36. The second layer 35B2 is a layer including a white pigment and is the same material as the support layer 35 of the first embodiment and the second embodiment, as an example. The thickness of the second layer 35B2 is thinner than the thickness of the first layer 35B1, as an example. From the above configuration, the first layer 35B1 is disposed between the insulating layer 32 and the second layer 35B2. In addition, the thickness of the support layer 35B of the present embodiment is thinner than the thickness of the phosphor layer 36, as an example.

### <Method for Manufacturing Phosphor Board of Third Embodiment>

Next, a description will be given of a method for manufacturing the phosphor board 30B of the present embodiment with reference to FIG. 9A to FIG. 9E. A method for manufacturing a light-emitting substrate 10B of the present embodiment includes a first step, a second step, a third step, a fourth step, and a fifth step, and each step is performed in the described order.

### [First Step]

This step is the same as in the case of the first embodiment (refer to FIG. 3A).

### [Second Step]

FIG. 9A is a diagram showing the start time and the end time of the first half of a second step and FIG. 9B is a diagram showing the end time of the first half (start time of the second half) and the end time of the second half (end time) of the second step. The second step (an example of the support layer forming step) is a step of forming the support layer 35B (the first layer 35B1 and the second layer 35B2) between the insulating layer 32 and the phosphor layer 36 formed in the third step. That is, this step (an example of the support layer forming step) is a step of forming the support layer 35B, which is a layer that does not include the phosphor and which supports the phosphor layer 36 formed in the third step, on the insulating layer 32. This step is divided into the first half of the step shown in FIG. 9A and the second half of the step shown in FIG. 9B.

In the first half of the step, paint (not shown), which is the base of the first layer 35B1, is coated on the portion of the surface 31 of the insulating layer 32 other than the portion where the circuit pattern layer 34 is disposed and the first layer 35B1 is formed (refer to FIG. 9A).

Next, in the second half of the step, white paint (not shown, the same as in the case of the first embodiment), which is the base of the second layer 35B2, is coated on the entire outer surface of the first layer 35B1 formed in the first half of the step and the non-bonding surface 34B1 of the circuit pattern layer 34 and the second layer 35B2 with an entirely flat outer surface is formed (refer to FIG. 9B).

When this step is completed, the support layer 35B (the first layer 35B1 and the second layer 35B2), which is a multilayer structure, is formed on the surface 31 of the insulating layer 32 at portions other than the portions where the circuit pattern layer 34 is disposed.

### [Third Step]

FIG. 9C is a diagram showing the start time and end time of the third step. The third step (an example of a phosphor layer forming step) is a step in which phosphor paint (not shown) is coated on the surface 31 side of the insulating layer 32 to form the phosphor layer 36. Specifically, in this step, phosphor paint (not shown) is coated on the outer surface of the support layer 35B formed in the second step (the outer surface of the second layer 35B2).

### [Fourth Step]

FIG. 9D is a diagram showing the start time and end time of the fourth step. The fourth step is a step of removing a part of the phosphor layer 36 and a part of the support layer 35B to expose all of the bonding surfaces 34A1 of the circuit pattern layer 34. The step of exposing the bonding surfaces 34A1 is performed in the same step as in the first and second embodiments, using a method of removal by laser beam irradiation or a method such as a photo printing method or a screen-printing method selected as appropriate. When this step is completed, the phosphor board 30B is manufactured.

### [Fifth Step]

FIG. 9E is a diagram showing the start time and end time of the fifth step. The fifth step (an example of a bonding step) is a step of mounting a plurality of the light-emitting elements 20 on the phosphor board 30B. This step is the same as the steps of the first and second embodiments illustrated in FIGS. 3E and 7D, where solder paste SP is printed on each of the bonding surfaces 34A1 by a reflow process and the plurality of the light-emitting elements 20 are mounted and bonded on each of the bonding surfaces 34A1. When this step is completed, the light-emitting substrate 10B is manufactured.

The foregoing was a description of the method for manufacturing the light-emitting substrate 10B of the present embodiment.

### <Light-Emitting Operation of Light-Emitting Substrate of Third Embodiment>

A light-emitting operation of the light-emitting substrate 10B of the present embodiment is basically the same as in the case of the second embodiment.

The foregoing was a description of the light-emitting operation of the light-emitting substrate 10B of the present embodiment.

### <Effects of Third Embodiment>

In the phosphor board 30B of the present embodiment, in the same manner as in the phosphor board 30A of the second embodiment (refer to FIG. 6), the entire region of the phosphor layer 36 is supported by the support layer 35B including a white pigment. Specifically, the phosphor layer 36 is disposed on the second layer 35B2 forming the support layer 35B. Therefore, according to the present embodiment, in the entire region of the phosphor layer 36, the reflection effect of the entire wavelength region of the excitation light, which is set to be visible light, may be improved.

In addition, unlike the phosphor board 30A of the second embodiment (refer to FIG. 6), in the phosphor board 30B of the present embodiment, the lower side portion of the support layer 35B is formed of the first layer 35B1 that does not include a white pigment. Therefore, the phosphor board 30B of the present embodiment is cheaper than the phosphor board 30A of the second embodiment.

Other effects of the present embodiment are the same as in the cases of the first embodiment and second embodiment.

The foregoing was a description of the effects of the present embodiment.

The foregoing was a description of the third embodiment.

### Fourth Embodiment

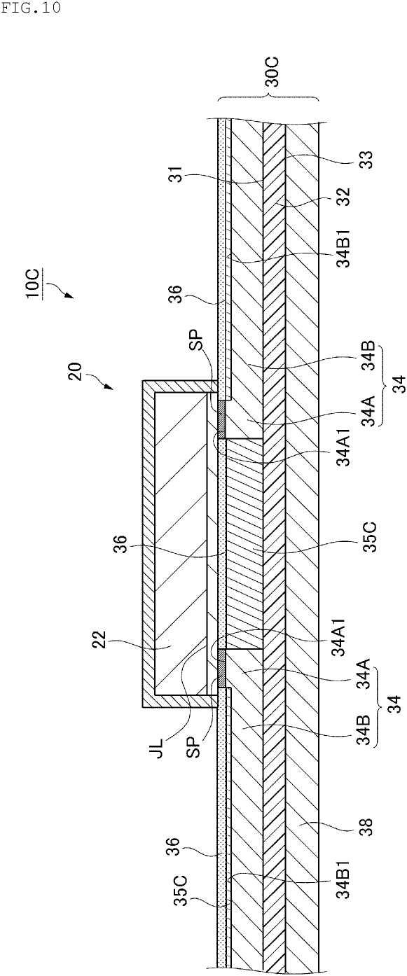

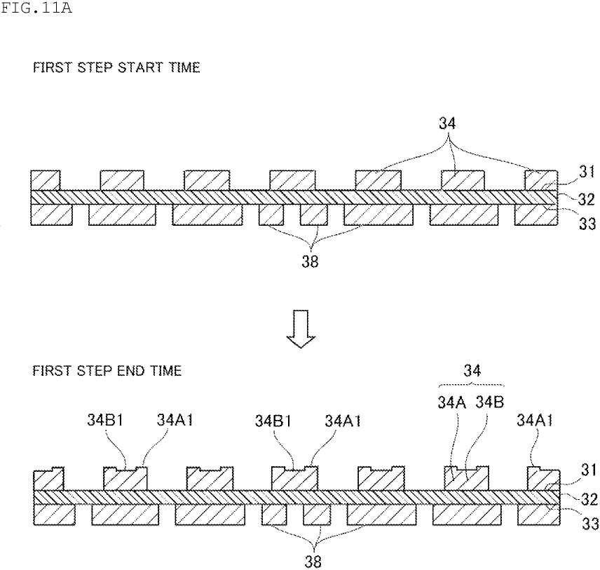

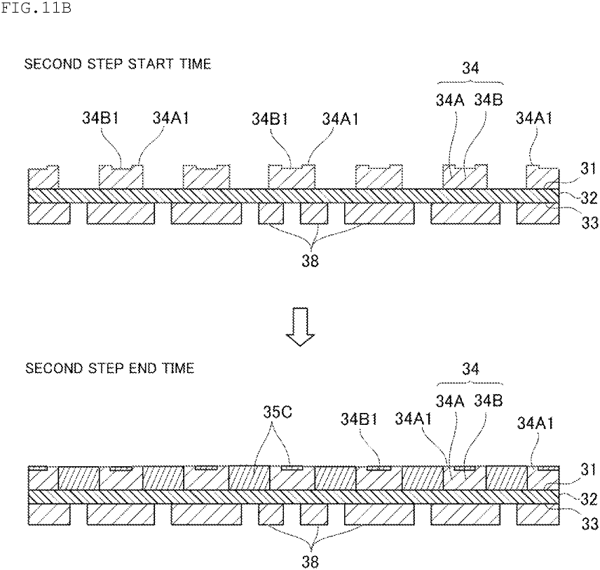

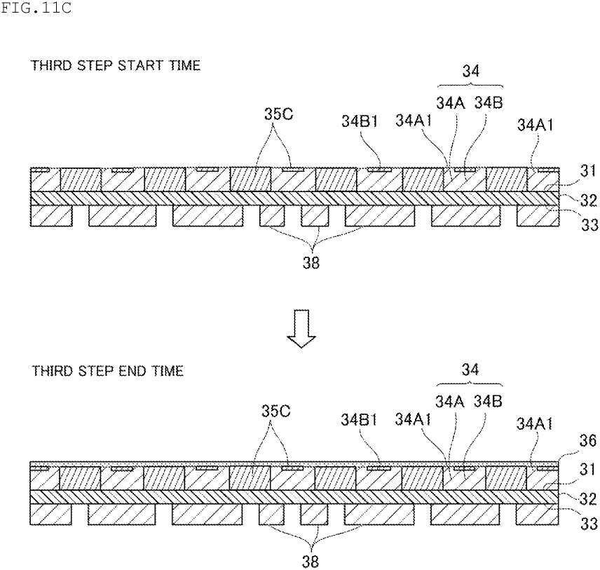

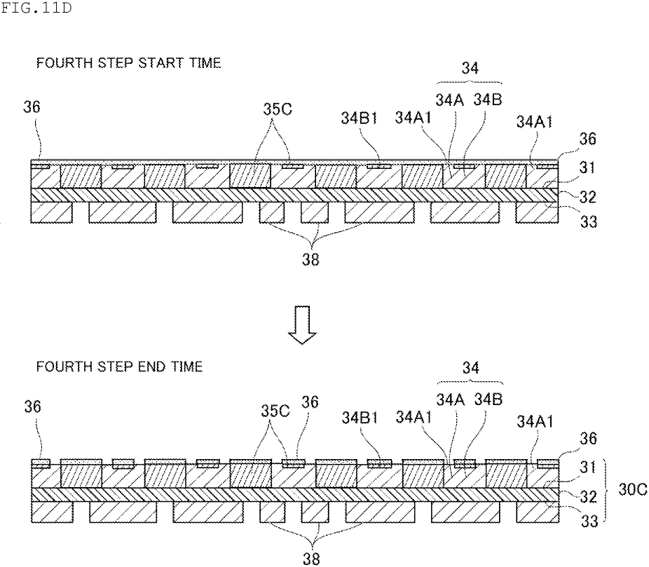

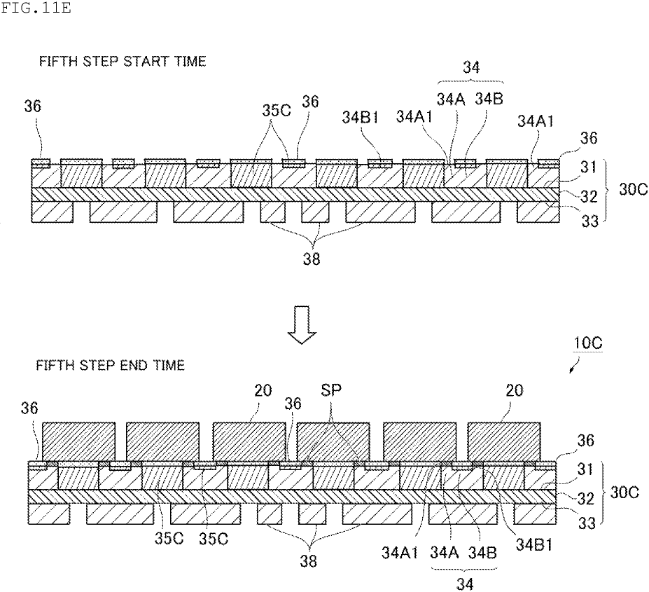

Next, a description will be given of the fourth embodiment with reference to FIG. 10 and FIG. 11A to FIG. 11E. A description will be given below of only those portions of the present embodiment that differ from the second embodiment (refer to FIG. 6 and the like) .

### <Configuration of Fourth Embodiment>

A phosphor board 30C of the present embodiment (refer to FIG. 10) differs from the phosphor board 30A of the second embodiment (refer to FIG. 6) in that the bonding surfaces 34A1 of the circuit pattern layer 34 are positioned outside a non-bonding surface 34A2 in the thickness direction of the insulating layer 32. In other words, in the case of the present embodiment, unlike the case of the second embodiment, each of the electrode pairs 34Aprotrudes from the wiring portion 34B to the outside in the thickness direction of the insulating layer 32.

### <Method for Manufacturing Phosphor Board of Fourth Embodiment>

Next, a description will be given of a method for manufacturing the phosphor board 30C of the present embodiment with reference to FIG. 11A to FIG. 11E. A method for manufacturing a light-emitting substrate 10C of the present embodiment includes a first step, a second step, a third step, a fourth step, and a fifth step, and each step is performed in the described order.

### [First Step]

FIG. 11A is a diagram showing the start time and end time of the first step. The first step is a step of forming the circuit pattern layer 34 on the surface 31A side of the motherboard MB and the rear surface pattern layer 38 on the rear surface 33A side.

In a case of forming the circuit pattern layer 34 in this step, first, a pattern of the same shape as the circuit pattern layer 34 viewed from the thickness direction is formed on the surface 31A side of the motherboard MB by etching using a mask pattern (not shown), for example. Next, a part (a portion corresponding to the wiring portion 34B) of the pattern is half-hatched (etched to the middle in the thickness direction) by etching using, for example, a mask pattern (not shown).

### [Second Step]

FIG. 11B is a diagram showing the start time and the end time of the first half of the second step. The second step (an example of a support layer forming step) is a step of forming a support layer 35C between the insulating layer 32 and the phosphor layer 36 formed in the third step. In this step, white paint (not shown, the same as in the case of the first embodiment) is coated on the surface 31 of the insulating layer 32 on portions other than the portion where the circuit pattern layer 34 is disposed and on all of the outer surfaces of the non-bonding surfaces 34B1 of the circuit pattern layer 34, and the support layer 35C is formed. In such a case, in this step, in a state where all of the electrode pairs 34A protrude from the outer surface of the support layer 35C, the outer surface of the support layer 35C is set to be flat across the entire area. When this step is completed, a layer with a monolayer structure including a white pigment is formed as the support layer 35C.

### [Third Step]

FIG. 11C is a diagram showing the start time and end time of the third step. The third step (an example of a phosphor layer forming step) is a step of forming the phosphor layer 36 by coating a phosphor paint (not shown) on the surface 31 side of the insulating layer 32. Specifically, in this step, the phosphor paint (not shown) is coated on the outer surface of the support layer 35C formed in the second step. In such a case, in this step, the phosphor layer 36 is formed such that all of the electrode pairs 34A are covered by the phosphor layer 36.

### [Fourth Step]

FIG. 11D is a diagram showing the start time and end time of the fourth step. The fourth step is a step of removing a part of the phosphor layer 36 to expose all of the bonding surfaces 34A1 of the circuit pattern layer 34. The step of exposing the bonding surfaces 34A1 is performed in the same step as in the first to third embodiments, using a method of removal by laser beam irradiation or a method such as a photo printing method or a screen-printing method selected as appropriate.

When this step is completed, the phosphor board 30C is manufactured.

### [Fifth Step]

FIG. 11E is a diagram showing the start time and end time of the fifth step. The fifth step (an example of a bonding step) is a step of mounting a plurality of the light-emitting elements 20 on the phosphor board 30C. This step is the same as the steps of the first to third embodiments illustrated in FIG. 3E, FIG. 7D, and FIG. 9E, where the solder paste SP is printed on each of the bonding surfaces 34A1 by a reflow process and a plurality of the light-emitting elements 20 are mounted and bonded on each of the bonding surfaces 34A1. When this step is completed, the light-emitting substrate 10C is manufactured.

The foregoing was a description of the method for manufacturing the light-emitting substrate 10C of the present embodiment.

### <Light-Emitting Operation of Light-Emitting Substrate of Fourth Embodiment>

A light-emitting operation of the light-emitting substrate 10C of the present embodiment is basically the same as that of the case of the second embodiment.

The foregoing was a description of the light-emitting operation of the light-emitting substrate 10C of the present embodiment.

### <Effects of Fourth Embodiment>

The effects of the present embodiment are the same as those of the case of the first embodiment, the second embodiment, and the third embodiment.

The foregoing was a description of the effects of the present embodiment.

The foregoing was a description of the fourth embodiment.

### Fifth Embodiment

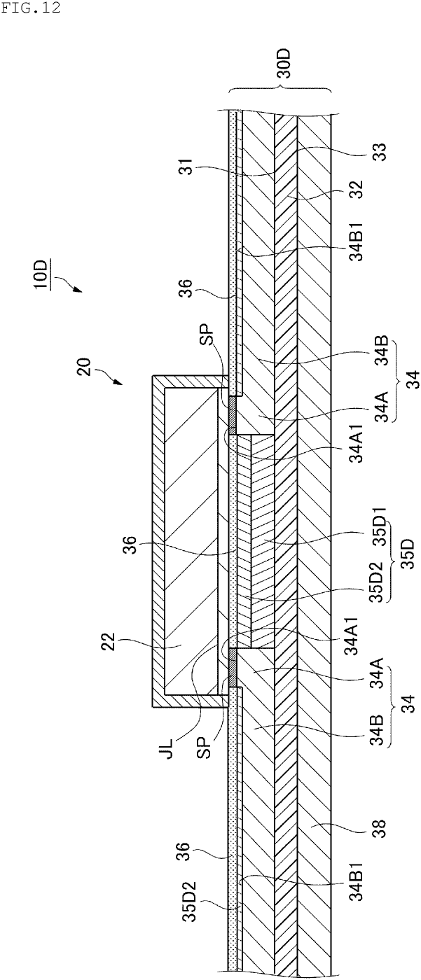

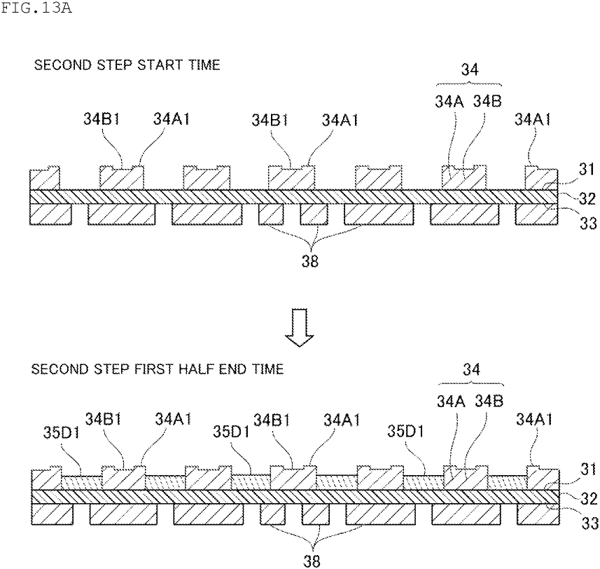

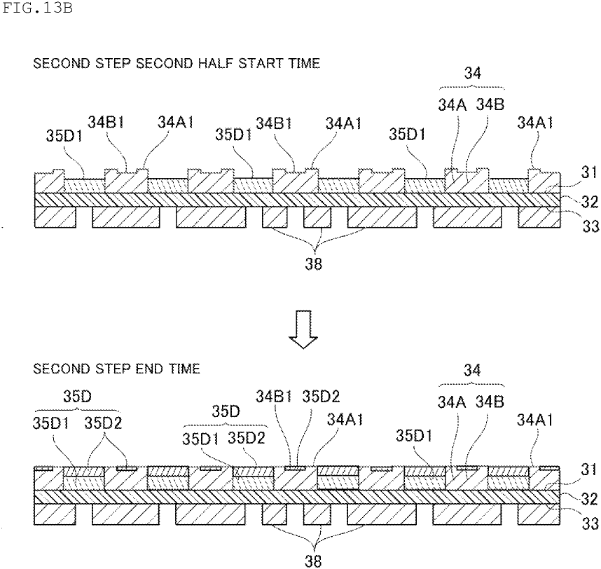

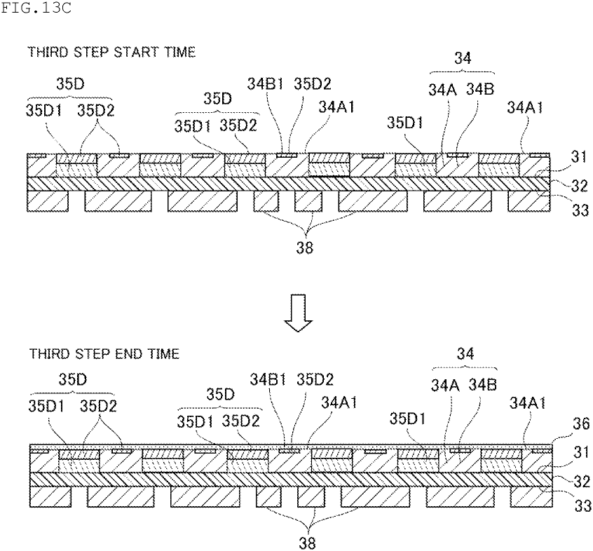

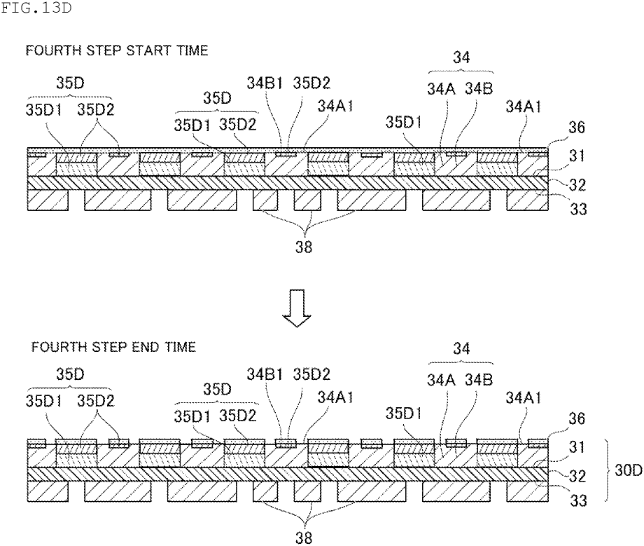

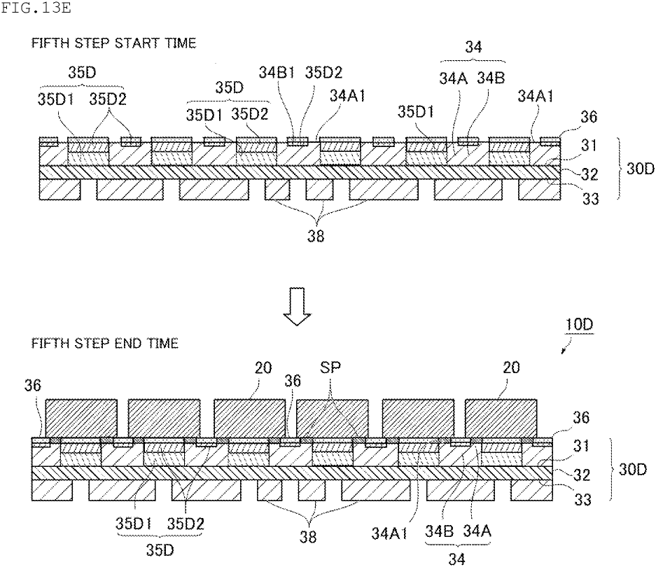

Next, a description will be given of the fifth embodiment with reference to FIG. 12 and FIG. 13A to FIG. 13E. A description will be given below of only those portions of the present embodiment that differ from the fourth embodiment (refer to FIG. 10 and the like) .

### <Configuration of Fifth Embodiment>

A phosphor board 30D of the present embodiment (refer to FIG. 12) differs from the phosphor board 30C of the fourth embodiment (refer to FIG. 10) in the point that a support layer 35D has a multilayer structure. Specifically, the support layer 35D of the present embodiment is formed of a first layer 35D1 (an example of a base layer) and a second layer 35D2 (an example of an adjacent layer) . The first layer 35D1 is disposed on the surface 31 of the insulating layer 32 at a portion other than the portion where the circuit pattern layer 34 is formed. The thickness of the first layer 35D1 is thinner than the thickness of the circuit pattern layer 34. The second layer 35D2 is disposed on the first layer 35D1 and the non-bonding surfaces 34B1 of the circuit pattern layer 34. Here, the first layer 35D1 is a layer that does not include a white pigment and is, as an example, the same layer as the first layer 35B1 of the third embodiment. In addition, a part of the second layer 35D2 is disposed between the first layer 35D1 and the phosphor layer 36 and another part is disposed between the circuit pattern layer 34 and the phosphor layer 36. That is, the second layer 35D2 is a layer that is adjacent to the phosphor layer 36. The second layer 35D2 is a layer including a white pigment and is the same material as the second layer 35B2 of the third embodiment, as an example. The thickness of the second layer 35D2 is thinner than the thickness of the first layer 35D1, as an example. From the above configuration, the first layer 35D1 is disposed between the insulating layer 32 and the second layer 35D2. In addition, the thickness of the support layer 35D of the present embodiment is thinner than the thickness of the phosphor layer 36, as an example.

### <Method for Manufacturing Phosphor Board of Fifth Embodiment>

Next, a description will be given of a method for manufacturing the phosphor board 30D of the present embodiment with reference to FIG. 13A to FIG. 13E. A method for manufacturing a light-emitting substrate 10D of the present embodiment includes a first step, a second step, a third step, a fourth step, and a fifth step, and each step is performed in the described order.

### [First Step]

This step is the same as in the case of fourth embodiment (refer to FIG. 11A).

### [Second Step]

FIG. 13A is a diagram showing the start time and the end time of the first half of a second step and FIG. 13B is a diagram showing the end time of the first half of a second step (start time of the second half) and the end time of the second half (end time). The second step (an example of support layer forming step) is a step of forming the support layer 35D between the insulating layer 32 and the phosphor layer 36 formed in the third step. That is, this step is a step of forming the support layer 35D, which is a layer that does not include phosphor and which supports the phosphor layer 36 formed in the third step, on the insulating layer 32. This step is divided into the first half of the step shown in FIG. 13A and the second half of the step shown in FIG. 13B.

In the first half of the step, paint (not shown), which is the base of the first layer 35D1, is coated on the surface 31 of the insulating layer 32 at portions other than the portions where the circuit pattern layer 34 is disposed and the first layer 35D1 (refer to FIG. 13A) is formed.

Next, in the second half of the step, a white paint (not shown, the same as in the case of the first embodiment), which is the base of the second layer 35D2, is coated on the first layer 35D1 formed in the first half of the step and on all of the outer surface of the non-bonding surfaces 34B1 of the circuit pattern layer 34 and the second layer 35D2 is formed (refer to FIG. 13B). In such a case, in this step, in a state where all of the electrode pairs 34A protrude further from the outer surface of the insulating layer 32 than the outer surface of the first layer 35D1, the outer surface of the support layer 35D is set to be flat across the entire area. When this step is completed, the support layer 35D with a multilayer structure is formed.

### [Third Step]

FIG. 13C is a diagram showing the start time and end time of the third step. The third step (an example of a phosphor layer forming step) is a step in which phosphor paint (not shown) is coated on the surface 31 side of the insulating layer 32 and the phosphor layer 36 is formed. This step is basically performed in the same manner as in the case of the fourth embodiment.

### [Fourth Step]

FIG. 13D is a diagram showing the start time and end time of the fourth step. The fourth step is a step of removing a part of the phosphor layer 36 to expose all of the bonding surfaces 34A1 of the circuit pattern layer 34. The step of exposing the bonding surfaces 34A1 is performed in the same step as in the first to fourth embodiments, using a method of removal by laser beam irradiation or a method such as a photo printing method or a screen-printing method selected as appropriate.

When this step is completed, the phosphor board 30D is manufactured.

### [Fifth Step]

FIG. 13E is a diagram showing the start time and end time of the fifth step. The fifth step (an example of a bonding step) is a step of mounting a plurality of the light-emitting elements 20 on the phosphor board 30D. This step is the same as the steps of the first to fourth embodiments illustrated in FIG. 3E, FIG. 7D, FIG. 9E, and FIG. 11E, where the solder paste SP is printed on each of the bonding surfaces 34A1 by a reflow process and a plurality of the light-emitting elements 20 are mounted and bonded on each of the bonding surfaces 34A1.

When this step is completed, the light-emitting substrate 10D is manufactured.

The foregoing was a description of the method for manufacturing the light-emitting substrate 10D of the present embodiment.

### <Light-Emitting Operation of Light-Emitting Substrate of Fifth Embodiment>

A light-emitting operation of the light-emitting substrate 10D of the present embodiment is basically the same as in the case of the second embodiment.

The foregoing was a description of the light-emitting operation of the light-emitting substrate 10D of the present embodiment.

### <Effect of Fifth Embodiment>

Unlike the phosphor board 30C of the fourth embodiment (refer to FIG. 10), in the phosphor board 30D of the present embodiment, the lower portion of the support layer 35D is formed of the first layer 35D1 that does not include a white pigment. Therefore, the phosphor board 30D of the present embodiment is cheaper than the phosphor board 30C of the fourth embodiment.

Other effects of the present embodiment are the same as in the cases of the first embodiment, second embodiment, third embodiment, and fourth embodiment.

The foregoing was a description of the effects of the present embodiment.

The foregoing was a description of the fifth embodiment.

Although each of the aforementioned embodiments is described above as examples of the present invention, the present invention is not limited to each of the aforementioned embodiments. The technical scope of the present invention includes, for example, the following forms (modifications).

For example, in the description of each of the embodiments, an example of the light-emitting element 20 was a CSP. However, an example of the light-emitting element 20 may be other than a CSP. For example, the light-emitting element 20 may simply be a flip chip. In addition, application to the substrate of a Chip On Board (COB) device itself is also possible.

In addition, in the description of each embodiment, the plurality of the light-emitting elements 20 were mounted on the phosphor board 30 and the light-emitting substrate 10 was provided with a plurality of the light-emitting elements 20. However, considering the mechanism of the description of the aforementioned first effect, it is clear that the first effect is achieved even if there is only one light-emitting element 20. Therefore, the number of light-emitting elements 20 mounted on the phosphor board 30 is at least one. In addition, there is at least one light-emitting element 20 mounted on the light-emitting substrate 10.

In addition, in the description of each embodiment, the outer side surface of the phosphor layer 36 in the thickness direction of the insulating layer 32 was positioned outside the circuit pattern layer 34 in the thickness direction (refer to FIG. 1C, FIG. 3D, and the like). However, considering the mechanism in the description of the aforementioned first effect, the outer side surface of the phosphor layer 36 in the thickness direction of the insulating layer 32 may be the same as the bonding surfaces 34A1 of the circuit pattern layer 34 in the thickness direction, or may be positioned inside the bonding surfaces 34A1 in the thickness direction.

In addition, in the description of each embodiment, the rear surface pattern layer 38 was provided on the rear surface 33A side of the phosphor board 30 (refer to FIG. 1B). However, considering the mechanism in the description of the aforementioned first effect, the rear surface pattern layer 38 may not be provided on the rear surface 33A side of the phosphor board 30.

In addition, in the description of the present embodiment, the phosphor layer 36 was disposed on the surface 31A side of the insulating layer 32 and the circuit pattern layer 34 at portions other than the plurality of electrode pairs 34A (refer to FIG. 2B). However, the phosphor layer 36 may not be disposed on the surface 31A side of the phosphor board 30 over all portions other than the plurality of electrode pairs 34A.

In addition, in the description of each embodiment, it was described that, when manufacturing the phosphor board 30 and the light-emitting substrate 10, the CS-3305A manufactured by Risho Kogyo Co., Ltd., was used as the motherboard MB. However, this is an example and a different motherboard MB may be used. For example, the present invention is not limited to the standard specifications such as insulating layer thickness and copper foil thickness of the CS-3305A manufactured by Risho Kogyo Co., Ltd., and in particular, an even thicker copper foil may be used.

It is possible to combine the light-emitting substrate 10 of each of the embodiments (also including modifications thereof) with other constituent components for application to a lighting device. The other constituent components in this case are a power supply that supplies power to make the light-emitting elements 20 of the light-emitting substrate 10 emit light, and the like.

In addition, in the third embodiment, the support layer 35B was described as a two-layer structure formed of the first layer 35B1 and the second layer 35B2 as a multilayer structure. However, as long as the support layer 35B includes a layer including a white pigment, the multilayer structure support layer 35B may be a structure with three or more layers. This point is the same for the case of the fifth embodiment.

This application claims priority based on Japanese Application No. 2020-144279 filed on Aug. 28, 2020, the entire disclosure of which is hereby incorporated herein.

### REFERENCE SIGNS LIST

10, 10A, 10B, 10C, 10D: light-emitting substrate
20: light-emitting element
22: LED
30, 30A, 30B, 30C, 30D: phosphor board
32: insulating layer (example of insulating substrate)
34: circuit pattern layer
34A: electrode pair
34A1: bonding surface
34A2: non-bonding surface
34B: wiring portion
34B1: non-bonding surface
35, 30B, 30C, 30D: support layer
35B1, 30D1: first layer
35B2, 30D2: second layer
36: phosphor layer
37: terminal
38: rear surface pattern layer
39: through hole
L: light
MB: motherboard
SP: solder paste

1. A phosphor board over which at least one light-emitting element is mounted, the phosphor board comprising:
an insulating substrate;
a circuit pattern layer which is disposed over one surface of the insulating substrate and which is to be bonded to the at least one light-emitting element;
a phosphor layer which is disposed over the one surface side of the insulating substrate and which includes phosphor for which a light emission peak wavelength is in a visible light region when emitted light of the at least one light-emitting element is used as excitation light; and
a support layer which is disposed between the insulating substrate and the phosphor layer, which is a layer that does not include the phosphor, and which supports the phosphor layer.

2. The phosphor board according to claim 1,
wherein the support layer has a monolayer structure including a white pigment.

3. The phosphor board according to claim 2,
wherein the support layer is also disposed between a portion of the circuit pattern layer other than a portion to be bonded to the at least one light-emitting element, and the phosphor layer.

4. The phosphor board according to claim 2,
wherein the support layer has a multilayer structure in which an adjacent layer that is adjacent to the phosphor layer includes a white pigment.

5. The phosphor board according to claim 4,
wherein the support layer is formed of the adjacent layer and a base layer which is disposed between the insulating substrate and the adjacent layer and which does not include the white pigment, and
a thickness of the adjacent layer is thinner than a thickness of the base layer.

6. The phosphor board according to claim 4,
wherein the adjacent layer is also disposed between a portion of the circuit pattern layer other than a portion to be bonded to the at least one light-emitting element, and the phosphor layer.

7. The phosphor board according to claim 2,
wherein the phosphor is formed of a plurality of phosphor particles, the white pigment is formed of a plurality of white particles, and
D1₅₀, which is a volume-based median diameter (D₅₀) of the plurality of phosphor particles measured by a laser diffraction scattering method, and D2₅₀, which is a volume-based median diameter (D₅₀) of the plurality of white particles measured by the laser diffraction scattering method, have a relationship as in (Equation 1)
$$0.8 \leq \text{D} {2}_{50} / \text{D} {1}_{50} \leq 1.2 \qquad \text{(Equation 1)}$$
.

8. The phosphor board according to claim 1,
wherein a thickness of the phosphor layer is thinner than a thickness of the support layer.

9. The phosphor board according to claim 1,
wherein an outer surface of the phosphor layer is positioned outside of an outer surface of the circuit pattern layer, in a thickness direction of the insulating substrate.

10. The phosphor board according to claim 1,
wherein the at least one light-emitting element is a plurality of light-emitting elements.

11. A light-emitting substrate comprising:
the phosphor board according to claim 1; and
the at least one light-emitting element.

12. A lighting apparatus comprising:
the light-emitting substrate according to claim 11; and
a power supply for supplying power to emit light from the at least one light-emitting element.
